(19) United States
(12) Patent Application Publication
(10) Pub. No.: US 2022/0368873 A1
(43) Pub. Date: Nov. 17, 2022

(54) IMAGE SENSOR, IMAGING APPARATUS, AND IMAGE PROCESSING METHOD

(71) Applicant: DENSO CORPORATION, Kariya-city (JP)

(72) Inventor: Kenji NAKAMURA, Kariya-city (JP)

(21) Appl. No.: 17/662,988

(22) Filed: May 11, 2022

(30) Foreign Application Priority Data
May 12, 2021 (JP) 2021-081240

(51) Int. Cl. H04N 9/64; H04N 9/04; H01L 27/146

(52) U.S. Cl. CPC H04N 9/646; H04N 9/0455; H01L 27/14645; H01L 27/14621

(57) ABSTRACT

An image sensor includes multiple photoelectric conversion elements and multiple individual color filters to generate multiple colors. The multiple individual color filters are arranged corresponding to the multiple photoelectric conversion elements, respectively. At least one of the multiple individual color filters includes a primary color type individual color filter. The primary color type individual color filter allows light of a corresponding primary color to permeate. The primary color type individual color filter has a first given transmittance for one of other primary colors other than the corresponding primary color, at which one of the other primary colors permeates the primary color type individual color filter. The first given transmittance is higher than a lower limit of a transmittance improving a sensitivity of the image sensor.

### CROSS-REFERENCE TO RELATED APPLICATION

This patent application is based on and claims priority to Japanese Patent

Application No. 2021-081240, filed on May 12, 2021 in the Japan Patent office, the entire disclosure of which is hereby incorporated by reference herein.

### BACKGROUND

### Technical Field

The present disclosure relates to an image sensor composed of a color filter, an imaging apparatus composed of the image sensor, and an image processing method used in the imaging apparatus.

### Related Art

An imaging apparatus composed of a color filter and a photoelectric conversion element is known. As the color filter, a three-color filter including red, green, and blue filters is often adopted. To enhance sensitivity, a known system adopts one of a yellow filter and a clear filter instead of the green filter.

However, the quality of images generated by the known system is not sufficient. That is because a level of a signal output from a pixel entered by a light beam passing through any one of the clear and yellow filters is different from that of a signal output from a pixel entered by a light beam passing through any one of the red and blue filters.

The present disclosure is made to address and resolve such a problem and it is an object of the present disclosure to provide a novel image sensor, an imaging apparatus, and an image processing method capable of reducing a difference in level of signal detected by each of photoelectric conversion elements thereby improving sensitivity.

### SUMMARY

Accordingly, one aspect of the present disclosure provides a novel image sensor that comprises multiple photoelectric conversion elements and multiple individual color filters to generate multiple colors. The multiple individual color filters are arranged corresponding to the respective multiple photoelectric conversion elements. At least one of the multiple individual color filters includes a primary color type individual color filter. The primary color type individual color filter transmits light of a corresponding primary color. The primary color type individual color filter also transmits light of at least one of other primary colors than the corresponding primary color. The primary color type individual color filter has a first given transmittance for one of the other primary colors other than the corresponding primary color, at which one of the other primary colors permeates through the primary color type individual color filter. The first given transmittance is higher than a lower limit of a transmittance improving a sensitivity of the image sensor. According to one aspect of the present disclosure, the sensitivity of the image sensor is more effectively improved than a conventional image sensor with a color filter having a transmittance for a primary color other than a corresponding primary color which is less than or equal to the lower effective transmittance.

Another aspect of the present disclosure provides a novel imaging apparatus that comprises: the above-described image sensor; and a processing circuit to generate a color image by processing signals output from the image sensor. The processing circuit generates the color image by using at least one of a first group of signals output from one or more photoelectric conversion elements correspondingly arranged to the primary color type individual filters and a second group of signals output from one or more photoelectric conversion elements correspondingly arranged to one or more sub-primary color filters. A correction coefficient used in correcting signals output from the one or more photoelectric conversion elements correspondingly arranged to the one or more primary color type individual filters and a correction coefficient used in correcting signals output from the one or more photoelectric conversion elements correspondingly arranged to the sub-primary color filter are different from each other.

Yet another aspect of the present disclosure provides a novel image processing method. The method comprises the steps of: receiving incident light with multiple color individual color filters; generating primary colors with a primary color filter section; and causing a part of the incident light to transmit a high sensitivity filter section having a higher sensitivity than the primary color filter section. The high sensitivity filter section is divided into multiple sub-high sensitivity filter sections. The multiple sub-high sensitivity filter sections are correspondingly arranged to the multiple photoelectric conversion elements, respectively.

The method also comprises the steps of: adjusting the number of photoelectric conversion elements used in generating a color of a single pixel in accordance with an ambient luminance; performing multiple photoelectric conversion with multiple photoelectric conversion elements correspondingly arranged to the multiple color individual color filters, respectively, to obtain electric signals; and correcting the electric signals.

The method also comprises the step of generating a color image based on the electric signals as corrected.

Hence, according to yet another aspect of the present disclosure, even if a degree of ambient brightness changes, a difference in level of a signal output from a photoelectric conversion element provided corresponding to a pixel can be reduced.

### BRIEF DESCRIPTION OF THE DRAWINGS

A more complete appreciation of the present disclosure and many of the attendant advantages of the present disclosure will be more readily acquired as substantially the same becomes better understood by reference to the following detailed description when considered with reference to the accompanying drawings, wherein:

FIG. 1 is a block diagram illustrating an imaging system 100 according to one embodiment of the present disclosure;

FIG. 2 is a side view schematically illustrating an exemplary vehicle that employs the system of FIG. 1 according to one embodiment of the present disclosure;

FIG. 3 is a plan view schematically illustrating the vehicle with the system illustrated in FIG. 2;

FIG. 4 is a plan view also schematically illustrating a vehicle with another system according to another embodiment of the present disclosure;

FIG. 5 is a plan view also schematically illustrating a vehicle including yet another system according to yet another embodiment of the present disclosure;

FIG. 6 is a plan view also schematically illustrating a vehicle including yet another system according to yet another embodiment of the present disclosure;

FIG. 7 is a block diagram illustrating an exemplary vehicle control system according to one embodiment of the present disclosure;

FIG. 8 is a diagram schematically illustrating an interior of a vehicle including a rearview mirror and a user interface to a vehicle imaging system according to one embodiment of the present disclosure;

FIG. 9 is a diagram schematically illustrating a camera mount disposed behind the rearview mirror while facing a vehicle windshield according to one embodiment of the present disclosure;

FIG. 10 is a diagram illustrating the camera mount of FIG. 9 when viewed from a different viewpoint from that of FIG. 9;

FIG. 11 is a diagram schematically illustrating another camera mount disposed behind the rearview mirror while facing the vehicle windshield according to one embodiment of the present disclosure;

FIG. 12 is a block diagram illustrating a memory that stores one or more instructions to perform one or more operations according to one embodiment of the present disclosure;

FIG. 13 is a flowchart illustrating an exemplary process of causing one or more navigation responses based on monocular image analysis according to one embodiment of the present disclosure;

FIG. 14 is a flowchart illustrating a process of detecting one or more vehicles and/or pedestrians in a set of images according to one embodiment of the present disclosure;

FIG. 15 is a flowchart illustrating a process of detecting road markings and/or lane geometry information in a set of images according to one embodiment of the present disclosure;

FIG. 16 is a flowchart illustrating a process of detecting a traffic light in a set of images according to one embodiment of the present disclosure;

FIG. 17 is a flowchart illustrating a process of causing one or more navigation responses based on a vehicle course according to one embodiment of the present disclosure;

FIG. 18 is a flowchart illustrating a process of determining whether a preceding vehicle is changing lane according to one embodiment of the present disclosure;

FIG. 19 is a flowchart illustrating a process of causing one or more navigation responses based on stereoscopic image analysis according to one embodiment of the present disclosure;

FIG. 20 is a flowchart illustrating a process of causing one or more navigation responses based on analysis performed based on three sets of images according to one embodiment of the present disclosure;

FIG. 21 is a cross sectional view illustrating components of an in-vehicle camera according to one embodiment of the present disclosure;

FIG. 22 is a first table illustrating an exemplary design rule to provide weightings according to a wavelength of a lens system according to one embodiment of the present disclosure;

FIG. 23 is a second table illustrating an exemplary design rule regarding a polychromatic MTF (Modulation Transfer Function) of a lens system according to one embodiment of the present disclosure;

FIG. 24 is a third table illustrating an exemplary design rule regarding parameters of a cut filter attached to a lens system according to one embodiment of the present disclosure;

FIG. 25 is a diagram schematically illustrating a configuration of an image sensor according to one embodiment of the present disclosure;

FIG. 26 is a cross-sectional view illustrating a front side illumination pixel according to one embodiment of the present disclosure;

FIG. 27 is a cross-sectional view illustrating a rear side illumination pixel according to one embodiment of the present disclosure;

FIG. 28 is a diagram illustrating a color filter array and a minimum repetition unit of a color filter according to one embodiment of the present disclosure;

FIG. 29 is a diagram illustrating a configuration of the minimum repetition unit of the color filter illustrated in FIG. 28;

FIG. 30 is a diagram illustrating a relation between a transmittance and a wavelength of incident light transmitted through a reddish individual color filter according to one embodiment of the present disclosure;

FIG. 31 is a diagram illustrating a relation between a transmittance and a wavelength of incident light transmitted through a green individual color filter according to one embodiment of the present disclosure;

FIG. 32 is a diagram illustrating a relation between a transmittance and a wavelength of incident light transmitted through a blue individual color filter according to one embodiment of the present disclosure;

FIG. 33 is a diagram illustrating a minimum repetition unit of a color filter according to a second embodiment of the present disclosure;

FIG. 34 is a block diagram schematically illustrating an imaging apparatus according to the second embodiment of the present disclosure;

FIG. 35 is a diagram illustrating a minimum repetition unit of a color filter according to a third embodiment of the present disclosure;

FIG. 36 is a diagram illustrating a minimum repetition unit of a color filter according to a fourth embodiment of the present disclosure;

FIG. 37 is a diagram illustrating a minimum repetition unit of a color filter according to a fifth embodiment of the present disclosure;

FIG. 38 is a block diagram schematically illustrating an imaging apparatus according to the fifth embodiment of the present disclosure; and

FIG. 39 is a block diagram schematically illustrating an imaging apparatus according to a sixth embodiment of the present disclosure.

### DETAILED DESCRIPTION

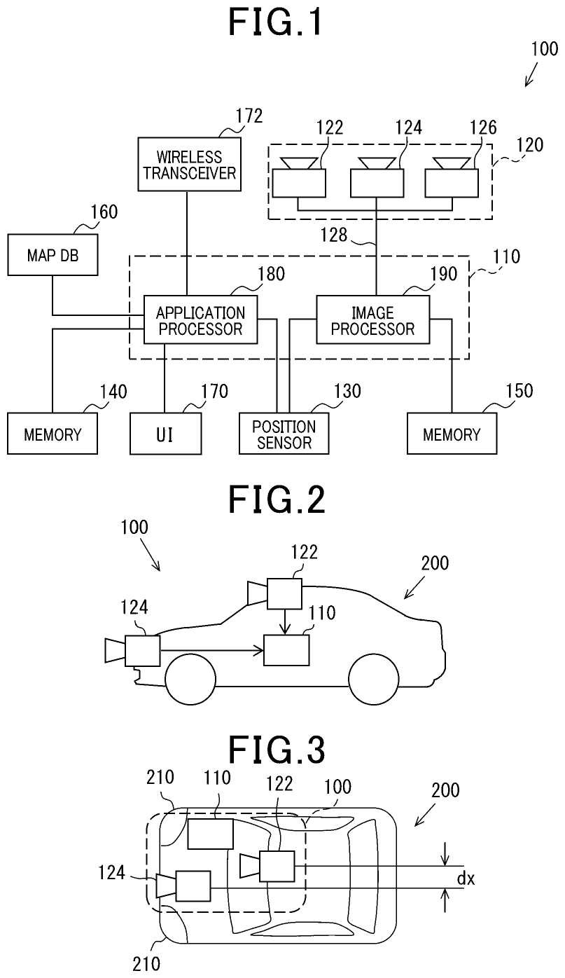

Referring now to the drawings, wherein like reference numerals designate identical or corresponding parts throughout the several views thereof and to FIGS. 1, an overview of a system is initially given. That is, FIG. 1 is a block diagram illustrating an exemplary imaging system 100 according to one embodiment of the present disclosure. The imaging system 100 may include various components meeting requirements for a specific implementation. In some embodiments, the imaging system 100 can include a processing unit 110, an image acquisition unit 120, and a position sensor 130. The imaging system 100 may also include one or more memories 140 and 150, a map database 160, and a user interface 170. The imaging system 100 may further include a wireless transceiver 172. The processing unit 110 may include one or more processors. In some embodiments, the processing unit 110 may include an application processor 180, an image processor 190, and any other optionally suitable processor. Similarly, the image acquisition unit 120 may include any number of image acquirers and components meeting requirements for a particular application. That is, the image acquisition unit 120 may include one or more image acquirers 122, 124 and 126. For example, each of the image acquirers is a camera. The imaging system 100 may also include a data interface 128 that connects the processing unit 110 with the image acquisition unit 120 to enable communication therebetween. For example, the data interface 128 may include any wired links and/or wireless links for transmitting image data acquired by the image acquisition unit 120 to the processing unit 110.

Further, the wireless transceiver 172 may include one or more devices configured to exchange transmission via a wireless interface with one or more networks (e.g., cellular networks, internet) by using a radio frequency or an infrared ray frequency in a magnetic field or an electric field. The wireless transceiver 172 can use any known standard to transmit and/or receive data.

Further, each of the application processor 180 and the image processor 190 may include various types of processors. For example, the application processor 180 and/or the image processor 190 may include a microprocessor, a preprocessor (e.g., an image preprocessor), and a graphics processor. The application processor 180 and/or the image processor 190 may also include a central processing unit (hereinbelow sometimes referred to as CPU), a support circuit, and a digital signal processor. The application processor 180 and/or the image processor 190 may further include an integrated circuit, a memory, and any other type of device suitable for executing applications, image processing, and analysis. In some embodiments, the application processors 180 and/or the image processors 190 may include any type of single-core or multi-core processor, a mobile device microcontroller, and a CPU or the like. Further, various processors may be used. Various architectures may also be included.

In some embodiments, the application processor 180 and/or the image processor 190 may include multiple processing units having a local memory and an instruction set. Such a processor and/or processors may include a video input function of receiving image data from multiple image sensors. The processor and/or processors may also include a video output function. As an example, the processor and/or processors can use a micron technology in a 90 nm-order capable of operating at about 332 MHz. Further, the architecture includes two floating-decimal point hyperthreaded 32-bit RISC (Reduced Instruction Set Computer)-CPUs, five vision calculation engines (VCEs), and three vector microcode processors. The architecture may also include a 64-bit mobile DDR (Double-Data-Rate) controller, a 128-bit internal acoustic interconnection, and a dual 16-bit video input. The architecture may be further composed of an 18-bit video output controller, a 16-channel DMA (Direct Memory Access), and multiple peripherals.

Further, any one of the processing units discussed in this disclosure may be configured to perform a specific function. To constitute a processor, such as a processor, a controller, a microprocessor, etc., performing such a specific function, computer-executable instructions may be programmed and are run by the processor to execute these instructions during operation of the processor. In other embodiments, the processor may directly be programmed by using architecture instructions. In yet other embodiments, the processor may store executable instructions in a memory accessible thereto during operation thereof. For example, the processor can obtain and execute the instructions stored in the memory by accessing the memory during operation thereof.

Further, although two separate processors are included in the processing unit 110 as illustrated in FIG. 1, more or fewer processors can be used. For example, in some embodiments, a single processor may be used to accomplish respective tasks of the application processor 180 and the image processor 190. In other embodiments, these tasks may be performed by two or more processors. Further, in some embodiments, the imaging system 100 may include one or more processing units 110 excluding other components, such as the image acquisition unit 120, etc.

Further, the processing unit 110 may be configured by various types of devices. For example, the processing unit 110 may include a controller, an image preprocessor, and a CPU. The processing unit 110 may also include a support circuit, a digital signal processor, and an integrated circuit. The processing unit 110 may also include a memory and any other type of devices used in image processing and analysis or the like. The image preprocessor may include a video processor for receiving images from image sensors, and digitizing and processing the images. The CPU may include any number of either microcontrollers or microprocessors. The support circuit may be any number of circuits commonly well-known in an applicable technical field, such as a cache circuit, a power supply circuit, a clock circuit, an input/output circuit, etc. The memory may store software that controls operation of the system when executed by the processor. The memory may also include a database or image processing software. Such a memory may include any number of RAMs (Random Access Memories), ROMs (Read-Only Memories), and flash memories. The memory may also be configured by any number of disk drives, optical storage devices, and tape storage devices. The memory may also be configured by any number of removable storage devices and other types of storage. In one example, the memory may be separate from the processing unit 110. In other embodiments, the memory may be integrated into the processing unit 110.

More specifically, each of the memories 140 and 150 may include (i.e., store) software instructions executed by the processor (e.g., the application processor 180 and/or the image processor 190) to control operations of various aspects of the imaging system 100. These memories 140 and 150 may further include various databases and image processing software. Each of the memories may include the random-access memory, the read-only memory, and the flash memory as described earlier. Each of the memories may also include a disk drive, an optical storage, and a tape storage. Each of the memories may further include a removable storage device and/or any other type of storage. In some embodiments, each of the memories 140 and 150 may be separated from the application processor 180 and/or the image processor 190. In another embodiment, each of the memories may be integrated into the application processor 180 and/or the image processor 190.

Further, the position sensor 130 may include any type of device suitable for determining a position of a component of the imaging system 100, such as an image acquirer, etc. In some embodiments, the position sensor 130 may include a GPS (Global Positioning System) receiver. Such a receiver can determine a position and a speed of a user by processing signals broadcasted by global positioning system satellites. Positional information output from the position sensor 130 may be utilized by the application processor 180 and/or the image processor 190.

Further, in some embodiments, the imaging system 100 may include a speed sensor (e.g., a tachometer) for measuring a speed of a vehicle 200 and/or an acceleration sensor for measuring a degree of acceleration of the vehicle 200.

Further, the user interface 170 may include any device suitable for the imaging system 100 in providing information to one or more users or in receiving inputs from one or more users. In some embodiments, the user interface 170 may include, for example, a user input device, such as a touch screen, a microphone, a keyboard, etc. The user input device can also be a pointer device, a track wheel, and a camera. The user input device can also be a knob and a button or the like. Hence, with such an input device, a user can enter instructions or information and voice commands. Also, the user can select menu options displayed on a screen by using the button, the pointer device, or an eye tracking function. The user can also input information or provide commands to the imaging system 100 through any other appropriate technologies for communicating information with the imaging system 100.

More specifically, the user interface 170 may include one or more processors configured to provide information to a user, receive information from a user and process the information for use in, for example, the application processor 180. In some embodiments, such a processor may execute instructions to recognize and track eye movement, to receive and interpret a voice command, and to recognize and interpret touching and/or gestures made on the touch screen. The processor may also execute instructions to respond to keyboard input or a menu selection and the like. In some embodiments, the user interface 170 may include a display, a speaker, and a tactile device for outputting information to a user. The user interface 170 may also include any other device.

Further, the map database 160 may include any type of database for storing useful map data to the imaging system 100. For example, in some embodiments, the map database 160 may include data connected with positions of various items in a reference coordinate system, such as a road, a water feature, a geographic feature, etc. The various items further include a business, a point-of-interest, and a restaurant. The various items further include a gas station or the like. In addition to these positions of such items, the map database 160 may store descriptors connected with such items, including names connected with any of the features as stored. In some embodiments, the map database 160 may be physically disposed together with other components of the imaging system 100. Either alternatively or additionally, at least part of the map database 160 may be located in a remote place far from other components of the imaging system 100 (e.g., the processing unit 110). In such embodiments, information may be downloaded from the map database 160 over a wired or wireless data connection to the network (e.g., via a cellular network and/or Internet).

Further, the image acquirers 122, 124 and 126 may each include any type of acquirers suitable for capturing at least a single image from an environment. Further, any number of image acquirers may be used to obtain images for input to the image processor. In some embodiments, only a single image acquirer may be included. In other embodiments, two or more image acquirers may be also included. The image acquirers 122, 124 and 126 are further described later in more detail with reference to FIGS. 2 to 6.

Further, the imaging system 100 or various components thereof may be incorporated into various platforms. In some embodiments, the imaging system 100 may be included in a vehicle 200 as illustrated in FIG. 2. For example, the vehicle 200 may include the processing unit 110 and any of other components of the imaging system 100 as described earlier with reference to FIG. 1. In some embodiments, the vehicle 200 can include only a single image acquirer (e.g., a camera). In other embodiments, multiple image acquirers may also be used as described with reference to FIGS. 3 to 20. For example, as illustrated in FIG. 2, any of the image acquirers 122 to 124 of the vehicle 200 may be a part of an ADAS (Advanced Driver Assistance Systems)—imaging set.

The image acquirer included in the vehicle 200 as a part of the image acquisition unit 120 may be disposed in any suitable position therein. Specifically, in some embodiments, the image acquirer 122 may be disposed near a rearview mirror 310 as illustrated in FIGS. 2 to 19 and 8 to 10. This position may provide the same line of sight as a driver driving the vehicle 200, which can help the drive to determine things as being visible or invisible. The image acquirer 122 may be disposed at any position near the rearview mirror 310. In particular, when the image acquirer 122 is placed on a driver side near the rearview mirror 310, such a position can further assist the driver in acquiring images representing a driver's field of view and/or a line of his or her sight.

Further, the image acquirer of the image acquisition unit 120 can be located at other places. For example, the image acquirer 124 can be disposed either on a bumper (not shown) of the vehicle 200 or in the bumper thereof. Because, such a position is particularly suitable for the image acquirer having a wide field of view. However, a line of sight of the image acquirer placed in the bumper may be different from a line of driver's sight. Hence, the bumper image acquirer and the driver do not always see the same object. Further, the image acquirer (e.g., the image acquirers 122, 124 and 126) can be disposed elsewhere. For example, the image acquirer can be placed on one or both sidemirrors, a roof and a bonnet of the vehicle 200. The image acquirer can also be placed on a trunk and a side of the vehicle 200. Furthermore, the image acquirer can be attached to one of windows of the vehicle 200, placed behind or in front of the vehicle 200, and mounted on or near front and/or rear lights of the vehicle 200.

In addition to the image acquirer, the vehicle 200 may include various other components of the imaging system 100. For example, the processing unit 110 may be integrated with or separately included from an electronic control unit (ECU) of the vehicle 200 in the vehicle 200. Further, the vehicle 200 may include the position sensor 130, such as the GPS receiver, etc., and the map database 160 and the memories 140 and 150.

Further, as described earlier, the wireless transceiver 172 may receive data over one or more networks. For example, the wireless transceiver 172 may upload data collected by the imaging system 100 to one or more servers. Also, the wireless transceiver 172 may download data from one or more servers. For example, via the wireless transceiver 172, the imaging system 100 may receive and update data stored in the map database 160, the memory 140, and/or the memory 150, periodically or on-demand. Similarly, the wireless transceiver 172 may upload any data, such as images taken by the image acquisition unit 120, data received by the position sensor 130, other sensors, and the vehicle control systems, etc., from the imaging system 100 to one or more servers. The wireless transceiver 172 may also upload any data processed by the processing unit 110 from the imaging system 100 to one or more servers.

Furthermore, the imaging system 100 may upload data to the server (e.g., a cloud computer) based on a privacy level setting. For example, the imaging system 100 may incorporate a privacy level setting to regulate or limit a type of data (including metadata) transmitted to the server, which can uniquely identify a vehicle and/or a driver or an owner of the vehicle. Such a privacy level setting may be achieved, for example, by a user via the wireless transceiver 172 or a factory default setting as an initial state. Also, the privacy level setting may be achieved by data received by the wireless transceiver 172.

More specifically, in some embodiments, the imaging system 100 may upload data in accordance with a privacy level. For example, in accordance with such a privacy level setting, the imaging system 100 may transmit data such as position information of a route, a captured image, etc., excluding details about a particular vehicle and/or a driver/an owner of the vehicle. Specifically, to upload data having high” privacy setting, the imaging system 100 may transmit data, such as a captured image excluding a vehicle identification number (VIN) or a name of a driver or owner, and/or limited position information of a route of the vehicle or the like.

Further, other privacy levels are also intended. For example, the imaging system 100 transmits data to a server having a medium privacy level by including additional information, such as a vehicle's maker, a model of a vehicle, a type of vehicle (e.g., a passenger vehicle, a sport utility vehicle, a truck), etc., excluded from the “high” privacy level. Also, in some embodiments, the imaging system 100 can upload data having a low privacy level. That is, with a “low” privacy level setting, the imaging system 100 may upload data including enough information to uniquely identify a particular vehicle, an owner/a driver and/or a part or all of a route driven by a vehicle. For example, data of such a “low” privacy level can include one or more information items, such as a VIN (Vehicle Identification Number), a name of a driver/an owner, an origin of a vehicle before departure, etc. The one or more information items also can be an intended destination of a vehicle, a maker and/or a model of a vehicle, and a type of vehicle or the like.

FIG. 2 is a side view schematically illustrating a representative imaging system 100 according to one embodiment of the present disclosure. FIG. 3 is an explanatory plan view of the embodiment illustrated in FIG. 2. As illustrated in FIG. 3, in this embodiment, a main body of a vehicle 200 may include an imaging system 100 having a first image acquirer 122 near a rearview mirror and/or a driver driving the vehicle 200, a second image acquirer 124 above or in a bumper section (e.g., one of bumper sections 210) of the vehicle 200, and a processing unit 110.

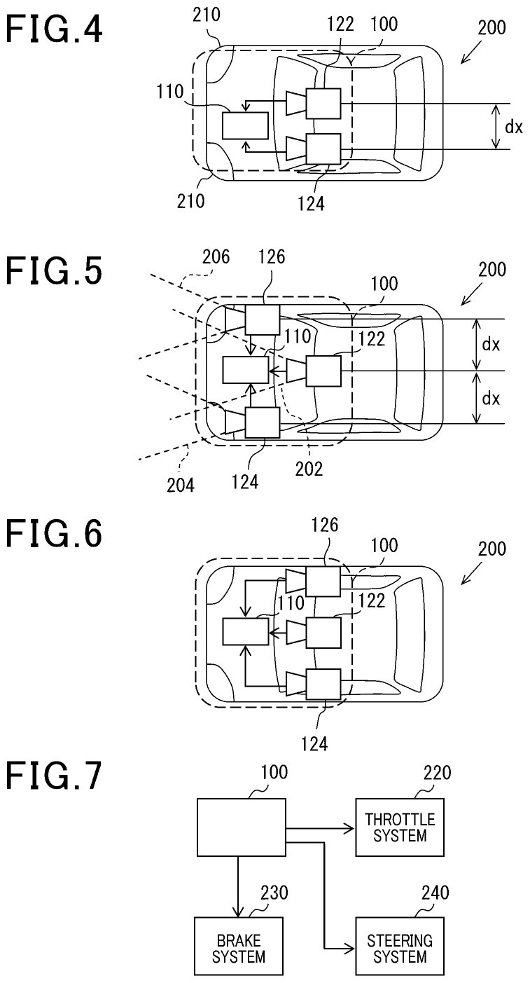

Further, as illustrated in FIG. 4, both of the image acquirers 122 and 124 may be located in the vicinity of the rearview mirror and/or the driver driving the vehicle 200. Although two image acquirers 122 and 124 are illustrated in each of FIGS. 3 and 4, other embodiments may employ three or more image acquirers. For example, in each of embodiments illustrated in FIGS. 5 and 6, the first image acquirer 122, the second image acquirer 124, and a third image acquirer 126 are employed in the imaging system 100.

Specifically, as illustrated in FIG. 5, the image acquirer 122 may be located near the rearview mirror and/or the driver of the vehicle 200. Then, the image acquirers 124 and 126 may be disposed on or within the bumper section (e.g., one of the bumper sections 210) of the vehicle 200. Otherwise, as illustrated in FIG. 6, the image acquirers 122, 124 and 126 may be disposed in the vicinity of the rearview mirror and/or a driver's seat of the vehicle 200. However, according to the embodiment of the present disclosure, the number and a configuration of image acquirers are not limited to a specific number and a specific configuration, and the image acquirer may be located in the vehicle 200 and/or in any suitable position above the vehicle 200.

Further, embodiments of the present disclosures are not limited to the vehicle and can be applied to other moving bodies. Further, the embodiments of the present disclosure are not limited to a particular type of vehicle 200, and are applicable to all types of vehicles including an automobile, a truck, a trailer, and other types of vehicles.

Further, the first image acquirer 122 may include any suitable type of image acquirer. Specifically, the image acquirer 122 includes an optical axis. As one example, the image acquirer 122 may include a WVGA (Wide Video Graphics Array) sensor having a global shutter. In other embodiments, the image acquirer 122 may have a resolution defined by 1280×960 pixels. The image acquirer 122 also may include a rolling shutter. The image acquirer 122 may include various optical elements. For example, in some embodiments, one or more lenses are included to provide a given focal length and a field of view to the image acquirer. For example, in some embodiments, the image acquirer 122 may employ either a 6 mm-lens or a 12 mm-lens. Further, in some embodiments, the image acquirer 122 may be configured to capture an image ranging in a given field of view (FOV) 202 as illustrated in FIG. 5. For example, the image acquirer 122 may be configured to have a regular FOV ranging from 40 to 56 degrees by including a 46-degree FOV, a 50-degree FOV, and a 52-degree FOV and more. Alternatively, the image acquirer 122 may be configured to have a narrow FOV in a range of from about 23 to about 40 degrees, such as a 28-degree FOV, a 36-degree FOV, etc. Furthermore, the image acquirer 122 may be configured to have a wide FOV in a range of from about 100 to about 180 degrees. For example, in some embodiments, the image acquirer 122 may include either a wide-angle bumper camera or a camera having a FOV of about 180 degrees at maximum.

Further, in some embodiments, the image acquirer 122 may have a resolution of 7.2 M pixels having a horizontal FOV of about 100 degrees with an aspect ratio of about 2:1 (e.g., H×V=3800×1900 pixels). Hence, such an image acquirer can be used instead of the three image acquirers 122, 124, and 126. In a situation where an image acquirer employs a rotationally symmetrical lens about an optical axis, a vertical FOV of such an image acquirer can become significantly smaller than about 50 degrees due to a large distortion of the lens. Such a lens is unlikely to be radially symmetric that causes a vertical FOV to be greater than about 50 degrees on condition that a horizontal FOV is about 100 degrees.

Further, the first image acquirer 122 may acquire multiple first images of a scene viewed from the vehicle 200. Each of the multiple first images may be acquired as a series of image scan lines or photographed by using a global shutter. Each of the scan lines may include multiple pixels.

The first image acquirer 122 may acquire a first series of image data on an image scan line at a given scanning rate. Here, the scanning rate may sometimes refer to a rate at which an image sensor can acquire image data of a pixel included in a given scan line.

Hence, each of the image acquirers 122, 124 and 126 can include any suitable type and the number of image sensors, such as CCD (Charge Coupled Diode) sensors, CMOS (Complementary Metal Oxide Semiconductor) sensors, etc. In one embodiment, the CMOS image sensor may be adopted together with a rolling shutter and reads each line of pixels one at a time and proceeds with scanning line by line until an image frame is entirely captured. Hence, rows are sequentially captured from top to bottom in the frame.

In some embodiments, one or more of the image acquirers (e.g., image acquirers 122, 124 and 126) may be one or more high-resolution imagers each having a resolution of one of 5 M pixels, 7 M pixels, and 10 M pixels, or more.

Here, when it is used, a rolling shutter can cause pixels in different columns to be exposed and photographed at different times from each other, thereby possibly causing skew and image artifacts in an image frame when captured. By contrast, when the image acquirer 122 is configured to operate by employing either a global shutter or a synchronous shutter, all pixels can be exposed at the same time during a common exposure period. As a result, image data in frames collected by the system employing the global shutter entirely represents a snapshot of a FOV (e.g., a FOV 202) at a given time period. By contrast, with a system employing the rolling shutter, each column in the frame image is exposed and data thereof is acquired from each line at a different timing. Hence, in an image acquirer having a rolling shutter, a moving object may seem to be distorted sometimes as described later in more detail.

Further, the second image acquirer 124 and the third image acquirer 126 may be any types of image acquirers. That is, as similar to the first image acquirer 122, each of the image acquirers 124 and 126 includes an optical axis. In one embodiment, each of the image acquirers 124 and 126 may include a WVGA sensor having a global shutter. Alternatively, each of the image acquirers 124 and 126 may include a rolling shutter. Similar to the image acquirer 122, each of the image acquirers 124 and 126 may be configured to include various lenses and optical elements. In some embodiments, each of lenses employed in the image acquirers 124 and 126 may have the same FOV (e.g., FOV 202) as employed in the image acquirer 122 or narrower than it (e.g., FOVs 204 and 206). For example, each of the image acquirers 124 and 126 may have a FOV of 40 degrees, 30 degrees, 26 degrees, 23 degrees, and 20 degrees or less.

Further, each of the image acquirers 124 and 126 may acquire multiple images of second and third images of a scene viewed from the vehicle 200. Each of the second and third images may be captured by using the rowing shutter. Each of the second and third images may be acquired as second and third series of image scan lines. Each scan line or row may have multiple pixels. Each of the image acquirers 124 and 126 may acquire each of image scan lines included in the second and the third series at second and third scanning rates.

Each image acquirer 122, 124 and 126 may be disposed at any suitable position facing a given direction on the vehicle 200. A positional relation between the image acquirers 122, 124 and 126 may be chosen to effectively perform information fusion for information acquired by these image acquirers. For example, in some embodiments, a FOV (e.g., a FOV 204) of the image acquirer 124 may overlap in part or completely with a FOV (e.g., a FOV 202) of the image acquirer 122 and a FOV (such as a FOV 206) of the image acquirer 126.

Further, each of the image acquirers 122, 124 and 126 may be disposed on the vehicle 200 at any suitable relative height. For example, a height can be different between the image acquirers 122, 124 and 126 to be able to provide sufficient parallax information enabling stereo analysis. For example, as illustrated in FIG. 2, the two image acquirers 122 and 124 are arranged at different heights. Further, a difference in lateral displacement is allowed between the image acquirers 122, 124 and 126 to provide additional parallax information for stereo analysis performed by the processing unit 110, for example. The difference in lateral displacement is indicated by a reference sign dx as illustrated in FIGS. 4 and 5. In some embodiments, an anterior or posterior part displacement (e.g., a displacement of a range) may be allowed between the image acquirers 122, 124 and 126. For example, the image acquirer 122 may be located from about 0.5 to about 2 meters or more behind the image acquirer 124 and/or the image acquirer 126. This type of displacement of image acquirers may allow one of the image acquirers to cover potential blind spots caused by the other multiple image acquirers.

Further, the image acquirer 122 may have any suitable resolution capability (e.g., a given number of pixels employed in an image sensor). The resolution of the image sensor of the image acquirer 122 may be the same as, or higher or lower than a resolution of each of image sensors employed in the image acquirers 124 and 126. For example, in some embodiments, image sensors of the image acquirers 122 and/or the image acquirers 124 and 126 may respectively have resolutions of about 640×480, about 1024×768, and about 1280×960, or any other suitable resolutions.

Further, the frame rate may be controllable. Here, the frame rate is defined as a rate at which an image acquirer acquires a set of pixel data constituting one image frame per unit time. Thus, the image acquirer moves to a stage of acquiring pixel data of the next image frame at the rate. The frame rate of the image acquirer 122 may be changed to be higher, lower, or even the same as each of the frame rates of the image acquirers 124 and 126. A timing of each of the frame rates of the image acquirers 122, 124 and 126 may be determined based on various factors. For example, a pixel latency may be included before or after acquiring image data of one or more pixels from one or more image acquirers 122, 124, and 126. In general, image data corresponding to each pixel can be acquired at a clock rate of an acquirer (e.g., a single pixel per clock cycle). Also, in some embodiments employing a rolling shutter, a horizontal blanking period may be selectively included before or after acquiring image data in a column of pixels of image sensors from one or more of the image acquirers 122, 124 and 126. Further, a vertical blanking period may be selectively included before or after acquiring image data of image frames from one or more of the image acquirers 122, 124 and 126

These timing controls enable synchronization of the frame rates of the image acquirers 122, 124 and 126, even in a situation where each line scanning rate is different. Further, as described later in more detail, these selectable timing controls enable synchronization of image capture from an area in which a FOV of the image acquirer 122 overlaps with one or more FOVs of the image acquirers 124 and 126, even if the field of view (FOV) of the image acquirer 122 differs from FOVs of the image acquirers 124 and 126.

A timing of a frame rate used in each of the image acquirers 122, 124 and 126 may be determined depending on a resolution of a corresponding image sensor. For example, when it is assumed that a similar line scanning rate is used in both acquirers and one of the acquirers includes an image sensor having a resolution of 640×480 while another acquirer includes an image sensor having a resolution of 1280×960, a longer time is required to obtain one frame of image data from the sensor having a higher resolution.

Another factor that may affect (or change) an acquisition timing of acquiring image data in each of the image acquirers 122, 124 and 126 is a maximum line scanning rate. For example, a minimum amount of time is required in acquiring a row of image data from image sensors arranged in each of the image acquirers 122, 124 and 126. Hence, if it is assumed that the pixel delay period is not additionally used (or employed), the minimum amount of time needed in acquiring a row of image data will affect a maximum line scanning rate of a given device. In such a situation, a device that offers a higher maximum line scanning rate may be able to provide a higher frame rate than a device that offers a lower maximum line scanning rate. Hence, in some embodiments, one or more of the image acquirers 124 and 126 may have a maximum line scanning rate higher than a maximum line scanning rate of the image acquirer 122. In some embodiments, the maximum line scanning rate of the image acquirers 124 and/or 126 may be one of about 1.25 times, about 1.5 times, and about 1.75 times of the maximum line scanning rate of the image acquirer 122. Otherwise, the maximum line scanning rate of the image acquirers 124 and/or 126 may be more than 2 times of the maximum line scanning rate of the image acquirer 122.

Further, in another embodiment, the image acquirers 122, 124 and 126 may operate at the same maximum line scanning rate. Also, only the image acquirer 122 may operate at a scanning rate below the maximum scanning rate. Further, a system may be configured such that one or more of the image acquirers 124 and 126 operate at a line scanning rate equal to a line scanning rate of the image acquirer 122. In another embodiments, a system may be configured such that a line scanning rate of the image acquirer 124 and/or the image acquirer 126 is one of about 1.25 times, about 1.5 times, and about 1.75 times as much as a line scanning rate of the image acquirer 122. Also, a system may be configured such that a line scanning rate of the image acquirer 124 and/or the image acquirer 126 is more than twice as much as a line scanning rate of the image acquirer 122.

Further, in some embodiments, the image acquirers 122, 124 and 126 may be asymmetrical. That is, these image acquirers 122, 124 and 126 may include cameras with different fields of view (FOV) and focal lengths from each other. For example, the field of view of each of the image acquirers 122, 124 and 126 may be any given area of environment of the vehicle 200. For example, in some embodiments, one or more of the image acquirers 122, 124 and 126 may be configured to obtain image data from ahead of the vehicle 200, behind the vehicle 200, and a side of the vehicle 200. Also, one or more of the image acquirers 122, 124 and 126 may be configured to obtain image data from a combination of these directions.

Further, a focal length of each image acquirer 122, 124 and/or 126 may be determined by selectively incorporating an appropriate lens to cause each acquirer to acquire an image of an object at a given distance from the vehicle 200. For example, in some embodiments, the image acquirers 122, 124 and 126 may obtain images of nearby objects within a few meters from the vehicle 200. The image acquirers 122, 124 and 126 may also be configured to obtain images of objects in a farther distance (e.g., 25 meters, 50 meters, 100 meters, 150 meters, or more) from the vehicle 200. Further, one image acquirer (e.g., the image acquirer 122) among the image acquirers 122, 124 and 126 may have a given focal length capable of obtaining an image of an object relatively close to the vehicle 200, for example, an object is located within 10 m or 20 m from the vehicle 200. In such a situation, the remaining image acquirers (e.g., the image acquirers 124 and 126) may have given focal lengths capable of obtaining images of objects located farther from the vehicle 200, for example, at a distance of one of 20 m, 50 m, 100 m, and 150 m or more.

Further, in some embodiments, a FOV of each of the image acquirers 122, 124 and 126 may have a wide angle. In particular, a FOV of 140 degrees may be advantageous for each of the image acquirers 122, 124 and 126 to capture images near the vehicle 200. For example, the image acquirer 122 may be used to capture images in left and right areas of the vehicle 200. In such a situation, it may be preferable sometimes for the image acquirer 122 to have a wide FOV. That is, the FOV may be at least 140 degrees.

Further, the field of view of each of the image acquirers 122, 124 and 126 depends on each focal distance. For example, the longer the focal length, the narrower the corresponding field of view.

Hence, the image acquirers 122, 124 and 126 may be configured to have any suitable field of view. In a given example, the image acquirer 122 may have a horizontal FOV of 46 degrees. The image acquirer 124 may have a horizontal FOV of 23 degrees. The image acquirer 126 may have a horizontal FOV between 23 degrees and 46 degrees. In other examples, the image acquirer 122 may have a horizontal FOV of 52 degrees. The image acquirer 124 may have a horizontal FOV of 26 degrees. The image acquirer 126 may have a horizontal FOV between 26 degrees and 52 degrees. In some embodiments, a ratio between the FOVs of the image acquirer 122 and the image acquirer 124 and/or the image acquirer 126 may vary from about 1.5 to about 2.0. In other embodiments, this ratio may vary between about 1.25 to about 2.25.

The imaging system 100 may be configured so that the field of view of the image acquirer 122 overlaps at least partially or completely with the field of view of the image acquirer 124 and/or the image acquirer 126. For example, in some embodiments, the imaging system 100 may be configured such that the fields of view of the image acquirers 124 and 126 fit within the field of view of the image acquirer 122 (e.g., these are narrower) and share a common center with the field of view of the image acquirer 122. In other embodiments, the image acquirers 122, 124 and 126 may capture adjacent FOVs. Also, there may be partial duplication (i.e., overlapping) in their FOVs. In some embodiments, the field of view of the image acquirers 122, 124 and 126 may be positioned so that a center of each other narrower FOV image acquirers 124 and/or 126 is located in a lower half of the field of view of the wider FOV image acquirer 122.

FIG. 7 is a block diagram illustrating an exemplary vehicle control system according to one embodiment of the present disclosure. As illustrated in FIG. 7, the vehicle 200 may include a throttle system 220, a brake system 230 and a steering system 240. The imaging system 100 may provide inputs (e.g., control signals) to one or more of the throttle systems 220, brake systems 230, and the steering systems 240 via one or more data links (e.g., links for transmitting data or any wired and/or wireless links). For example, based on analysis of images obtained by the image acquirers 122, 124 and/or 126, the imaging system 100 may provide control signals to one or more systems of the throttle system 220, the brake system 230, and the steering system 240 to control these systems to respectively perform, for example, acceleration, turning, and lane shifting or the like. Further, the imaging system 100 may receive inputs indicating an operation condition of a vehicle 200 (e.g., speed, braking and/or turning of the vehicle 200) from one or more systems of the throttle system 220, the brake system 230 and the steering system 240. Further details are described later with reference to FIGS. 12 to 20.

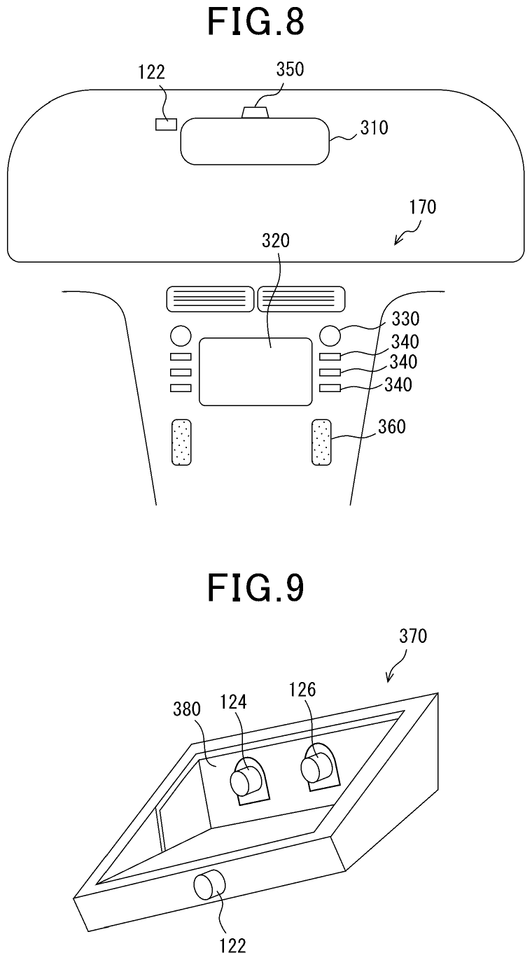

Further, as illustrated in FIG. 8, the vehicle 200 may include a user interface 170 used in interacting with a driver or occupants in the vehicle 200. For example, a user interface 170 is included in a vehicle application and may include a touch screen 320, a knob 330 and a button 340. The user interface 170 may also include a microphone 350. Further, the driver or the occupants in the vehicle 200 may interact with the imaging system 100 using a steering wheel and a button or the like. The handle includes a turn signal handle located on or near a steering column of the vehicle 200, for example. The buttons are disposed on the steering wheel of the vehicle 200, for example. In some embodiments, the microphone 350 may be disposed adjacent to the rearview mirror 310. Similarly, in some embodiments, the image acquirer 122 may be located near the rearview mirror 310. In some embodiments, the user interface 170 may include one or more speakers 360 (e.g., speakers used in a vehicle audio system). The imaging system 100 may provide various notifications (e.g., alerts) to the driver via the speaker 360.

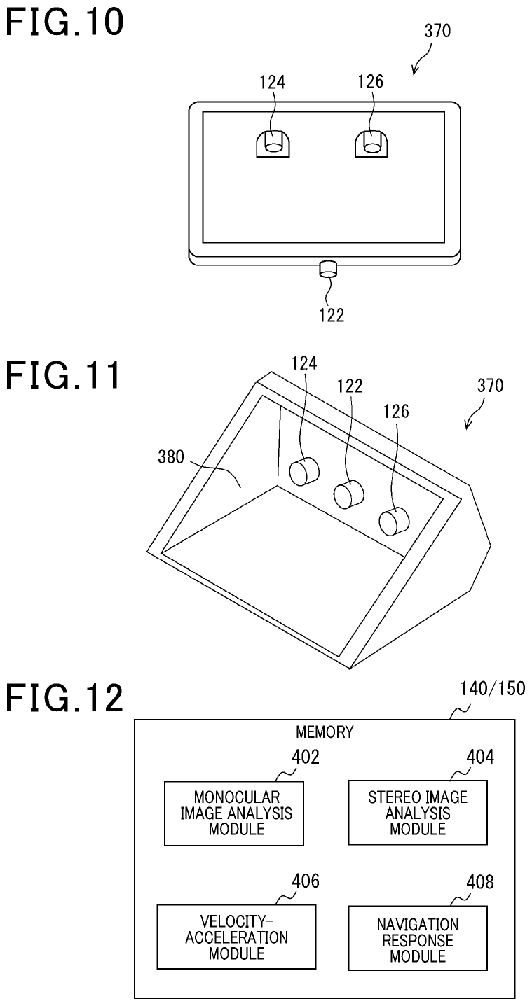

FIGS. 9 to 11 illustrate exemplary camera mounts 370 disposed face to face to a vehicle windshield behind the rearview mirror (e.g., rearview mirror 310) according to one embodiment of the present disclosure. Specifically, as illustrated in FIG. 9, the camera mount 370 may include image acquirers 122, 124 and 126. The image acquirers 124 and 126 may be disposed behind the glare shield 380. The glare shield 380 may be the same height as the vehicle windshield and include a film and/or a composition of antireflection material. For example, the glare shield 380 may be arranged facing the windshield of a vehicle. The glare shield 380 and the windshield have the same inclination as each other. In some embodiments, each of the image acquirers 122, 124 and 126 may be disposed behind a glare shield 380, as illustrated in FIG. 1, for example. However, the present disclosure is not limited to any specific configuration of the image acquirers 122, 124 and 126, the camera mount 370, and the glare shield 380. FIG. 10 is a front view illustrating the camera mount 370 illustrated in FIG. 9.

As will be appreciated by those skilled in the art, many variants and/or modifications of the present disclosure described heretofore can be made. For example, not all components are required in operating the imaging system 100. Further, any component may be disposed in any other suitable sections in the imaging system 100. The components may also be relocated while providing the same function performed in the embodiment of the present disclosure. Thus, the afore-mentioned configuration is just an example, and the imaging system 100 can provide a wide range of functions to analyze images of surroundings of the vehicle 200 and navigate the vehicle 200 in accordance with the analysis.

Further, as will be described hereinbelow in more detail, according to various embodiments of the present disclosure, the imaging system 100 may provide various functions related to autonomous driving and/or a driver assistance technology. For example, the imaging system 100 may analyze image data, position data (e.g., GPS position information), map data, velocity data and/or data transmitted from sensors included in the vehicle 200. The imaging system 100 may collect data for analysis from the image acquisition unit 120, the position sensor 130 and other sensors, for example. Further, the imaging system 100 can analyze the collected data and determine based thereon whether the vehicle 200 should take certain actions, and automatically take action as determined without human intervention. For example, when the vehicle 200 is navigated without human intervention, the imaging system 100 may automatically control braking, acceleration and/or steering of the vehicle 200 by transmitting control signals to one or more systems of the throttle system 220, the brake system 230, and the steering system 240, respectively. Further, the imaging system 100 may analyze collected data and issue a warning and/or alarm to an occupant in the vehicle based on the analysis thereof. Hereinbelow, details about various functions provided by the imaging system 100 are additionally described.

Specifically, as described above, the imaging system 100 may provide a drive assistance function by using a multi-camera system. The multi-camera system may use one or more cameras facing forward of the vehicle. In other embodiments, the multi-camera system may include one or more cameras facing either sideward or behind the vehicle. For example, in one embodiment, the imaging system 100 may use two camera imaging systems, where a first camera and a second camera (e.g., image acquirers 122 and 124) may be disposed in front of and/or on a side of the vehicle 200. The first camera may have a field of view larger (wider) or smaller (narrower) than a field of view of the second camera. Otherwise, the first camera may have a field of view partially overlapping with a field of view of the second camera. Further, the first camera may be connected to a first image processor to perform monocular image analysis of images provided by the first camera. The second camera may be connected to a second image processor to provide images and allow the second image processor to perform monocular image analysis thereof. Outputs (e.g., processed information) of the first and second image processors may be combined with each other. In some embodiments, the second image processor may receive images from both of the first camera and the second camera and perform stereo analysis thereof. In other embodiments, the imaging system 100 may use three camera imaging systems with cameras each having a different field of view from the other. In such a system, determination is made based on information from objects located in front and both sides of the vehicle at various distances. Here, the monocular image analysis means a situation where images taken from a single viewpoint (for example, a single camera) are analyzed. By contrast, the stereo image analysis means image analysis performed based on two or more images taken by using one or more image shooting parameters. For example, images suitable for the stereo image analysis are those taken either from two or more different positions or in different fields of view. Also, images suitable for stereo image analysis are those taken either at different focal lengths or with parallax information and the like.

Further, in one embodiment, the imaging system 100 may employ three camera systems by using the image acquirers 122, 124 and 126, for example. In such a system, the image acquirer 122 may provide a narrow field of view (e.g., a value of 34 degrees, a value selected from a range from about 20 degrees to about 45 degrees). The image acquirer 124 may provide a wide field of view (e.g., a value of 150 degrees, a value selected from a range from about 100 degrees to about 180 degrees). The image acquirer 126 may provide an intermediate field of view (e.g., a value of about 46 degrees, a value selected from a range from about 35 degrees to about 60 degrees). In some embodiments, the image acquirer 126 may act as either a main camera or a primary camera. These image acquirers 122, 124 and 126 may be separately placed at an interval (e.g., about 6 cm) behind the rearview mirror 310 substantially side-by-side. Further, in some embodiments, as described earlier, one or more of the image acquirers 122, 124 and 126 may be attached to a back side of the glare shield 380 lying on the same plane as the windshield of the vehicle 200. Such a shield 380 can function to minimize any reflection of light from an interior of the vehicle, thereby reducing affection thereof on the image acquirers 122, 124, and 126.

Further, in another embodiment, as described earlier with reference to FIGS. 9 and 10, the wide field of view camera (e.g., the image acquirer 124 in the above-described example) may be attached to a position lower than the narrow field of view camera and the main field of view camera (e.g., the image acquirers 122 and 126 in the above-described example). With such a configuration, a line of sight from the wide field of view camera may be freely provided. Here, the camera may be mounted near the windshield of the vehicle 200 or include a polarizer to reduce an amount of reflected light.

Further, the three-camera system can provide a given performance (i.e., characteristics). For example, in some embodiments, detection of an object performed by a first camera is verified by another second camera based on a result of detection thereof by the second camera as one function. Further, for the three-camera system, the processing unit 110 may include three processors (i.e., first to third processors), for example. Each processor exclusively processes images captured by one or more of the image acquirers 122, 124 and 126.

With the three-camera systems, a first processor may receive images from both the main camera and the narrow-visual field camera. The first processor may then apply vision processing to the images transmitted from the narrow-visual field camera and detect other vehicles, pedestrians, and lane markings. The first processor may also detect traffic signs, traffic lights, and other road objects or the like. The first processer may also calculate a parallax of a pixel between the image transmitted from the main camera and the image transmitted from the narrow visual field camera. The first processer may then create a 3D (three-Dimensional) reconstruction (image) of environment of the vehicle 200. The first processer may combine such a 3D reconstructed structure with 3D map data or 3D information calculated based on information transmitted from the other cameras.

A second processer may receive images from the main camera, applies visual processing thereto and detect other vehicles, pedestrians, and lane markings. The second processer may also detect traffic signs, traffic lights and other road objects. Further, the second processer may calculate an amount of displacement of the camera and calculate a parallax of a pixel between successive images based on the amount of displacement. The second processer may then create a 3D reconstruction of a scene (e.g., a structure from motion). The second processer may then send the 3D reconstruction generated based on the structure from motion to the first processor and synthesize it with a stereo 3D image.

A third processer may receive an image from a wide-angle camera. The third processer may then process the image and detect objects on a road, such as vehicles, pedestrians, lane markings, traffic signs, traffic lights, etc. Further, the third handling apparatus may execute additional processing instructions and analyze the image, thereby identifying a moving object, such as a vehicle, a pedestrian, etc., that changes a lane, in the image.

In some embodiments, a system can have redundancy by independently receiving and processing a stream of image-based information. For example, such redundancy includes verifying and/or supplementing information obtained by capturing image information from at least the second image acquirer and applying a given processing thereto by using the first image acquirer and an image processed by the first image acquirer.

Further, in some embodiments, when it performs navigation assistance to the vehicle 200, the imaging system 100 may provide redundancy to verify analysis of data received from the other two image acquirers (e.g., the image acquirers 122 and 124) by using the third image acquirer (e.g., the image acquirer 126). For example, with such a system, the image acquirers 122 and 124 may provide images for stereo analysis performed by the imaging system 100 in navigating the vehicle 200. At the same time, to provide the redundancy and the verification of information obtained based on images captured by and transmitted from the image acquirer 122 and/or the image acquirer 124, the image acquirer 126 may provide images to the imaging system 100 to be used in monocular analysis therein. That is, the image acquirer 126 and the corresponding processor thereto can be regarded as a system that provides a redundant subsystem for checking on analysis of images (e.g., an automatic emergency braking (AEB) system) obtained from the image acquirers 122 and 124.

Here, the above-described configuration, arrangement, and the number of cameras are just one examples. Also, the above-described position and the like of the camera are only one examples. Specifically, these components of the entire system described heretofore can be assembled and used in various methods without departing from a gist of the above-described embodiment. Also, other configurations not described heretofore can be additionally assembled and used without departing from the gist of the above-described embodiments. Herein below, a system and a method of using the multi-camera systems that provide driver assistance and an autonomous vehicle operating function are described in more detail.

FIG. 12 is a block diagram illustrating exemplary functions of each of memories 140 and 150 that stores programs and instructions for performing one or more operations according to one embodiment of the present disclosure. Hereinbelow, although the memory 140 is typically referred to, instructions may be stored in both memories 140 and 150.

Specifically, as illustrated in FIG. 12, the memory 140 may store a monocular image analysis module 402, a stereo image resolution module 404, and a velocity-acceleration module 406. The memory 140 may also store a navigation response module 408. However, the present disclosure is not limited to any specific configuration of the memory 140. For example, the application processor 180 and/or the image processor 190 may execute instructions stored in any one or more of the modules 402, 404, 406, and 408 included in the memory 140. Hereinbelow, although the processing unit 110 is typically described, the application processor 180 and the image processor 190 can individually or collectively operate similarly. That is, any one or more steps of the below described process may be performed by one or more processors.

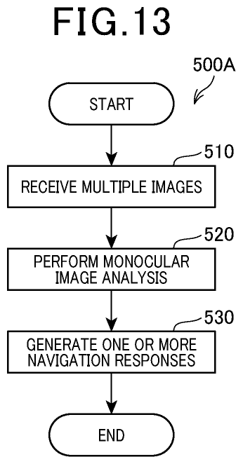

In one embodiment of the present disclosure, the monocular image analysis module 402 may store instructions, such as computer vision software, etc., that perform monocular image analysis analyzing a set of images obtained by one of the image acquirers 122, 124 and 126, when executed by the processing unit 110. In some embodiments, the processing unit 110 may perform monocular image analysis based on a combination formed by combining information of the set of images with additional sensor information (e.g., information obtained from radar). As described hereinbelow with reference to FIGS. 13 to 16, the monocular image analysis modulus 402 may include (i.e., store) instructions to detect a set of features included in a set of images, such as lane markings, vehicles, pedestrians, etc. The set of features may also be road signs, highway exit ramps, and traffic lights. The set of features may also be dangerous goods and other features related to environment of the vehicle or the like. For example, based on the analysis, the imaging system 100 may control the vehicle 200 via the processing unit 110 to cause one or more navigation responses, such as turning, lane shifting, and a change in acceleration, etc., as described later with reference to the navigation response module 408.

In one embodiment, the stereo image analysis module 404 may store instructions, such as computer vision software, etc., to perform stereo image analysis analyzing first and second sets of images obtained by a combination of any two or more of image acquirers selected from the image acquirers 122, 124, and 126. In some embodiments, the processing unit 110 may perform the stereo image analysis based on information of the first and second image sets in combination with additional sensor information (e.g., information obtained from radar). For example, the stereo image analysis module 404 may include instructions to execute stereo image analysis based on the first set of images acquired by the image acquirer 124 and the second set of images acquired by the image acquirer 126. As will be described hereinbelow with reference to FIG. 19, the stereo image analysis module 404 may include instructions to detect a set of features in the first and second image sets, such as lane markings, vehicles, pedestrians, etc. The set of features may also be road signs, highway exit ramps, and traffic lights. The set of features may also be dangerous goods or the like. Based on the analysis, the processing unit 110 may control the vehicle 200 to cause one or more navigation responses, such as turnings, lane shifting, and changes in acceleration as described later regarding the navigation response module 408.

Further, in some embodiments, the velocity-acceleration module 406 may store software configured to analyze data received from one or more computers and electromechanical devices installed in the vehicle 200 to cause changes in speed and/or acceleration of the vehicle 200. For example, the processing unit 110 may execute instructions stored in the velocity-acceleration module 406 and calculates a target speed of the vehicle 200 based on data obtained by executing instructions of the monocular image analysis module 402 and/or the stereo image analysis module 404. Such data may include a target position, a speed and/or an acceleration. The data may also include a position and/or a speed of a vehicle 200 relative to a nearby vehicle, a pedestrian and/or a road object. The data may further include positional information of the vehicle 200 relative to a road lane marking or the like. Further, the processing unit 110 may calculate the target speed of the vehicle 200 based on a sensor input (e.g., information from radar) and an input from other systems installed in the vehicle 200, such as a throttle system 220, a brake system 230, a steering system 240, etc. Hence, based on the target speed as calculated, the processing unit 110 may transmit electronic signals to the throttle system 220, the brake system 230, and/or the steering system 240 of the vehicle 200 to cause these systems to change in speed and/or acceleration, for example, by physically stepping on a brake of the vehicle 200 or loosening (i.e., easing up on) an accelerator.

Further, in one embodiment, the navigation response module 408 may store software that can be executed by the processing unit 110 to determine given navigation responses based on data obtained by executing the monocular image analysis modules 402 and/or the stereo image analysis module 404. Such data may include position and speed information regarding nearby vehicles, pedestrians, and road objects. The data may also include position and speed information regarding information of a target position targeted by the vehicle 200, or the like. Further, in some embodiments, the navigation response may be generated partially or completely based on map data, a position of a vehicle 200, and/or a relative velocity or acceleration of a vehicle 200 to one or more objects as detected by executing the monocular image analysis module 402 and/or the stereo image analysis module 404. The navigation response module 408 may also determine given navigation responses based on a sensor input (e.g., information from radar) and inputs from other systems installed in the vehicle 200, such as the throttle system 220, the brake system 230, the steering system 240, etc. Then, to trigger a given navigation response of the vehicle 200 and cause the vehicle 200 to rotate the steering wheel thereof at a given angle, for example, the processing unit 110 may transmit electronic signals to the throttle system 220, the brake system 230, and the steering system 240. Here, in some embodiments, the processing unit 110 may use an output of the navigation response module 408 (e.g., a given navigation response) as an input for executing instructions of the velocity-acceleration module 406 that calculates a change in speed of the vehicle 200.

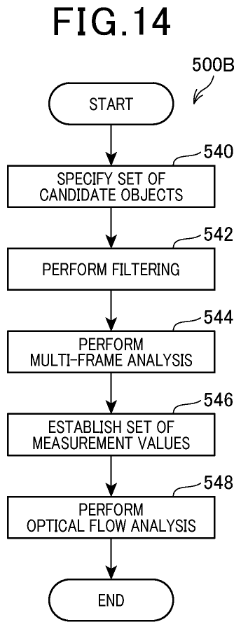

FIG. 13 is a flowchart illustrating an exemplary process 500A of producing one or more navigation responses based on monocular image analysis according to one embodiment of the present disclosure. As shown, in step S510, the processing unit 110 may receive multiple images via the data interface 128 located between the processing unit 110 and the image acquisition unit 120. For example, a camera included in the image acquisition unit 120 (e.g., the image acquirer 122 having the field of view 202) may capture multiple images in one of a forward area both side areas, and a back side area of the vehicle 200, for example, and transmit these images to the processing unit 110 via a data connection. Here, the data connection may be either a wired connection or a wireless connection. As described later in more detail with reference to FIGS. 14 to 16, the processing unit 110 may execute instructions of the monocular image analysis module 402 in step 520 and analyze the multiple images.

Subsequently, by performing analysis in this way, the processing unit 110 may detect a series of features included in a series of images, such as lane markings, vehicles, pedestrians, road signs, etc. The processing unit 110 may also detect a series of features included in a series of images, such as high-speed road exit ramps, traffic lights, etc.

Subsequently, in step S520, the processing unit 110 may also execute instructions in the monocular image analysis module 402 to detect various road hazards, such as pieces of a truck tire, fallen road signs, loose cargo, small animals, etc. Since structures, shapes, and sizes of such road hazards are likely to vary, detection of such hazards can become more difficult. Also, since colors of the road hazards can also vary, detection of such hazards can become more difficult again. In some embodiments, the processing unit 110 may execute instructions in the monocular image analysis module 402 and perform multi-frame analysis analyzing multiple images, thereby detecting such road hazards. For example, the processing unit 110 may estimate movement of the camera caused between successive image frames, calculate a parallax of a pixel between frame images, and construct a 3D map of a road. Subsequently, the processing unit 110 may detect a road surface and a danger present on the road surface based on the 3D map.

Subsequently, in step S530, the processing unit 110 may execute instructions of the navigation response module 408 and causes the vehicle 200 to generate one or more navigation responses, based on the analysis performed in step S520 while using the technology described earlier with reference to FIG. 12. The navigation response may include turning, lane shifting, and a change in acceleration or the like, for example. Here, in some embodiments, the processing unit 110 may cause one or more navigation responses by using data obtained as a result of execution of instructions of the velocity-acceleration module 406. Furthermore, multiple navigation responses may occur simultaneously or in a sequence. Also, multiple navigation responses may occur in any combination of these methods of occurrence of the responses. For example, the processing unit 110 may cause the vehicle 200 to accelerate after shifting beyond one lane, by sequentially transmitting control signals to the steering system 240 and the throttle system 220 of the vehicle 200 in order. Alternatively, the processing unit 110 may cause the vehicle 200 to brake and shift a lane at the same time by simultaneously transmitting control signals to the brake system 230 and the steering system 240 of the vehicle 200.

FIG. 14 is a flowchart also illustrating an exemplary process 500B of detecting one or more vehicles and/or pedestrians in a series of images according to another embodiment of the present disclosure. Specifically, the processing unit 110 may execute instructions of the monocular image analysis module 402 for the purpose of performing the process 500B. That is, in step S540, the processing unit 110 may select a set of candidate objects possibly representing one or more vehicles and/or pedestrians. For example, the processing unit 110 may scan one or more images and compare the images with one or more given patterns. The processing unit 110 may then identify a place in each image that may possibly include an object of interest (e.g., the vehicle, the pedestrian, a part thereof). The given pattern may be designed to enhance a percentage of false hits while decreasing a percentage of overlooking (e.g., missed identification). For example, the processing unit 110 may utilize a threshold showing less similarity to a given pattern for the purpose of identifying the objects as possible candidates for the vehicles or the pedestrians. With this, the processing unit 110 can reduce probability of overlooking of candidate objects representing vehicles or pedestrians.

Subsequently, in step S542, the processing unit 110 may filter the set of candidate objects for the purpose of excluding given candidates (e.g., unrelated or irrelevant objects) based on one or more classification criterion. Such one or more criterion may be derived from various characteristics related to a type of object stored in a database (e.g., a database stored in the memory 140). Here, the various characteristics may include a shape, a dimension, and a texture of the object. The various characteristics may also include a position (e.g., a position relative to the vehicle 200) of the object and the like. Thus, the processing unit 110 may reject false candidates from the set of object candidates by using one or more sets of criteria.

Subsequently, in step S544, the processing unit 110 may analyze images of multiple frames and determine whether one or more objects in the set of candidate objects represent vehicles and/or pedestrians. For example, the processing unit 110 may track the candidate objects as detected in successive frames and accumulate data of the objects (e.g., a size, a position relative to the vehicle 200) per frame. Further, the processing unit 110 may estimate parameters of one or more objects as detected and compare position data of the one or more objects included in each frame with one or more estimated positions.

Subsequently, in step S546, the processing unit 110 may generate a set of measurement values of one or more objects as detected. Such measurement values may include positions, velocities, and acceleration values of the detected one or more objects relative to the vehicle 200, for example. In some embodiments, the processing unit 110 may generate the measurement values based on an estimation technology, such as a Kalman filter, a linear quadratic estimation (LQE), etc., that uses a series of time-based observation values. Also, the processing unit 110 may generate the measurement values based on available modeling data of different object types (e.g., automobiles, trucks, pedestrians, bicycles, road signs). The Kalman filter may be based on measurement values of scales of objects. Such scale measurement values are proportional to a time to collision (e.g., a time period until a vehicle 200 reaches the object). Hence, by executing steps from S540 to S546, the processing unit 110 may identify vehicles and pedestrians appearing in the series of images as photographed and derive information (e.g., positions, speeds, sizes) of the vehicles and the pedestrians. Then, based on the identified and derived information in this way, the processing unit 110 may cause the vehicle 200 to generate one or more navigation responses as described heretofore with reference to FIG. 13.

Subsequently, in step S548, the processing unit 110 may perform optical flow analysis analyzing one or more images and detects a false hit, thereby reducing a probability of missing candidate objects representing vehicles or pedestrians. Here, the optical flow analysis can be analysis of analyzing a pattern of movement relative to the vehicle 200, which is different from movement of a road surface in one or more images of other vehicles and pedestrians. Further, the processing unit 110 can calculate movement of the one or more candidate objects by observing a change in position of the one or more candidate objects in multiple image frames taken at different times. Here, the processing unit 110 may use positions and times as inputs to a mathematical model for calculating movement of the one or more candidate objects. In this way, the optical flow analysis can provide another method of detecting vehicles and pedestrians present near the vehicle 200. Subsequently, in step S548, the processing unit 110 may perform optical flow analysis in combination with the processes of steps S540 to S546 in order to provide redundancy for the purpose of detecting the vehicles and pedestrians thereby increasing reliability of the imaging system 100.

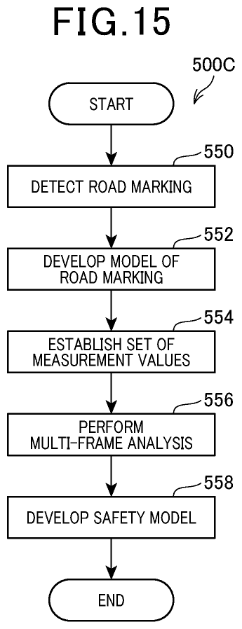

FIG. 15 is a flowchart illustrating an exemplary process 500C of detecting road markings and/or lane geometry information in a set of images according to one embodiment of the present disclosure. Specifically, the processing unit 110 may execute instructions in the monocular image analysis model 402 for the purpose of performing the process 500C. Hence, in step S550, the processing unit 110 may detect a series of objects by scanning one or more images. In order to detect lane marking segments, lane geometry information, and other suitable road markings, the processing unit 110 may filter the series of objects and exclude given objects determined as being irrelevant (e.g., small holes, small stones). Subsequently, in step S552, the processing unit 110 may group segments detected in step S550 as belonging to the same road marking or lane marking. Based on such grouping, the processing unit 110 may develop a model, such as a mathematical model, etc., representing the segments as detected.

Subsequently, in step S554, the processing unit 110 may generate a set of measurement values of the segments as detected. In some embodiments, the processing unit 110 may generate a projection of the segments as detected by projecting the segments from an image plane to a real-world plane. The projection may be characterized by using a third order polynomial composed of coefficients corresponding to physical characteristics, such as a position, an inclination, a curvature, a curvature differentiation, etc., of a road as detected. When generating the projection, the processing unit 110 may use information of a change in road surface and pitch and roll rates of the vehicle 200. Further, the processing unit 110 may model a height of the road by analyzing hints of a position and movement present on the road surface. Here, the hint of the position may be a position, an inclination, and a curvature of a road as detected. Also, a detected curvature differentiation value of the road and the like can be the hint. The hint of the movement includes a pitch rate and/or a roll rate of a vehicle or the like. That is, based on these hints, a height and an inclination of the road is estimated.

Further, the processing unit 110 may estimate the pitch and roll rate of the vehicle 200 by tracking a set of feature points included in one or more images.

Subsequently, in step S556, the processing unit 110 may perform multi-frame analysis, for example, by tracking segments successively detected in image frames and accumulating data of the segments per image frame. When the processing unit 110 performs the multiple frame analysis, the set of measurement values generated in step

S554 can become more reliable. Hence, the set of measurement values can be assigned an increasingly higher confidence level. As such, by executing the steps from S550 to S556, the processing unit 110 can identify road markings appearing in the set of images as captured, thereby becoming possible to derive lane geometry information. Based on information as identified and derived in this way, the processing unit 110 may cause the vehicle 200 to generate one or more navigation responses as described earlier with reference to FIG. 13.

Subsequently, in step S558, the processing unit 110 may utilize additional sources of information to further develop a safety model of the vehicle 200 in view of surrounding conditions. Specifically, the processing unit 110 may define a condition on which the imaging system 100 can perform autonomous control of the vehicle 200 in safety by using the safety model. For example, in some embodiments, to develop the safety model, the processing unit 110 may utilize information of a position and movement of other vehicle, an edge and a barrier of a road as detected, and/or a description of a shape of a general road derived from map data, such as data in the map database 160, etc. Further, by using additional sources of information, the processing unit 110 may provide redundancy in detecting road markings and lane shapes, thereby enhancing a reliability of the imaging system 100.

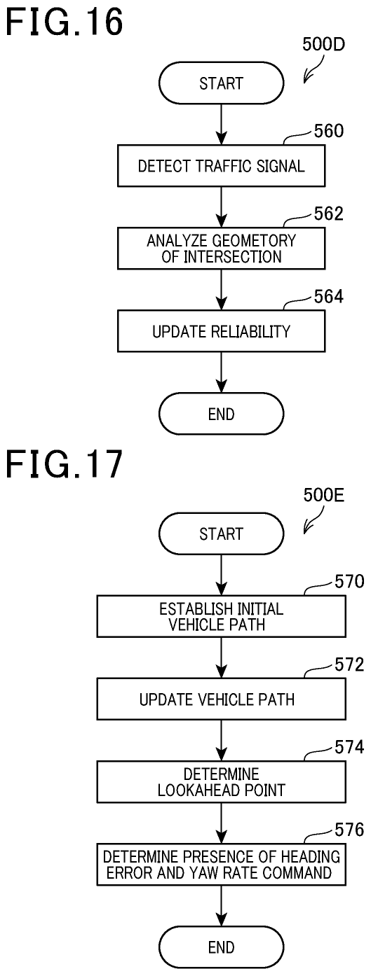

FIG. 16 is a flowchart illustrating an exemplary process 500D of detecting traffic signals in a series of images according to one embodiment of the present disclosure. Specifically, the processing unit 110 may execute instructions of the monocular image analysis module 402 and performs the process 500D. Hence, in step S560, the processing unit 110 may scan a series of images and identify objects appearing at positions in the image likely to include traffic signals. For example, the processing unit 110 may generate a set of candidate objects by applying a filtering process to objects as identified and excluding (i.e., filtering out) applicable objects unlikely to correspond to a traffic light. Such filtering may be performed based on various characteristics of a traffic light, such as a shape, a dimension, a texture, a position (e.g., position relative to a vehicle 200), etc. Such characteristics may be stored in a data base as multiple examples of traffic signals and traffic control signals. Here, in some embodiments, the processing unit 110 may perform multi-frame analysis based on a set of candidate objects that possibly reflect a traffic signal. For example, the processing unit 110 may track candidate objects over successive image frames and estimate real-world positions of the candidate objects, thereby filtering out moving objects, which are unlikely to be traffic lights. Further, in some embodiments, the processing unit 110 may perform color analysis of analyzing the candidate objects and identify relative positions of colors appearing and detected in an applicable traffic light.

Subsequently, in step S562, the processing unit 110 may analyze a shape of an intersection. The analysis may be performed based on any combination of the below listed first to third information. The first information is the number of lanes detected on both sides of a vehicle 200. The second information is markings detected on a road, such as arrow markings, etc. The third information is description of an intersection extracted from map data, such as data extracted from a map database 160, etc. Then, the processing unit 110 may analyze information obtained by executing instructions of the monocular image analysis module 402. Then, in step S560, the processing unit 110 may determine if the traffic light detected in step S560 corresponds to one or more lanes appearing in the vicinity of the vehicle 200.

Subsequently, in step 564, as the vehicle 200 approaches a junction (the intersection), the processing unit 110 may update a confidence level assigned to a geometry of the intersection as analyzed and a traffic light as detected. That is, a result of comparison (i.e., difference) between the number of traffic lights estimated to appear at the intersection and the number of traffic lights actually appearing at the intersection can change the confidence level. Accordingly, in accordance with the reliability level, the processing unit 110 may entrust control to a driver of the vehicle 200 in order to improve safety. Hence, the processing unit 110 may identify the traffic lights appearing in a set of images as captured and analyze the geometry information of the intersection by executing the steps S560 to S564. Subsequently, based on the identification and the analysis, the processing unit 110 may cause the vehicle 200 to generate one or more navigation responses as described earlier with reference to FIG. 13.

FIG. 17 is a flowchart illustrating an exemplary process 500E of controlling a vehicle 200 to generate one or more navigation responses based on a course of the vehicle according to one embodiment of the present disclosure. That is, in step S570, the processing unit 110 may establish a vehicle course in an initial stage of the vehicle 200. The vehicle course may be represented by an assembly of points represented by coordinates (x, z). In the assembly of points, a distance “d” between two points may range from about 1 meter to about 5 meters. In one embodiment, the processing unit 110 may establish (i.e., construct) the vehicle course of the initial stage by using two polynomials of a left road polynomial and a right road polynomial. The processing unit 110 may calculate geometric midpoints each defined between two points obtained by calculating these two polynomials, thereby obtaining the vehicle course as a calculation result. A given offset (e.g., so-called smart lane offset) may be given to each of the geometric midpoints if it is present. Hence, if the offset is zero, the vehicle may correspondingly travel along the middle of the lanes. Here, the offset may be directed perpendicular to a segment defined between any two-point in the vehicle course. In another embodiment, the processing unit 110 may define the vehicle course based on one polynomial and a half of an estimated lane width. Then, a given offset (e.g., so-called smart lane offset) is added to each half point in the vehicle course.

Subsequently, in step S572, the processing unit 110 may update the vehicle course established in step S570. Specifically, the processing unit 110 may reconstruct (i.e., reestablish) the vehicle course established in step S570 by using a higher resolution so that a distance dₖ between two points in an assembly of points representing the vehicle course is smaller than the distance di (d) described earlier. For example, the distance dₖ may range from about 0.1 meter to about 0.3 meters. More specifically, the processing unit 110 may reconstruct the vehicle course by using a parabolic spline algorithm. That is, with the algorithm, the processing unit 110 may obtain a cumulative distance vector S based on an assembly of points representing the total length of the vehicle course.

Subsequently, in step S574, the processing unit 110 may determine a lookahead point represented by (X₁, Z₁) in the coordinates based on the vehicle course as updated in step S572. Here, the processing unit 110 may extract the lookahead point based on the cumulative distance vector S. The lookahead point can be a lookahead distance and a lookahead time. The lookahead distance may be calculated as a product of a speed of the vehicle 200 and the lookahead time with a lower limit ranging from about 10 m to about 20 m. For example, when the speed of the vehicle 200 decreases, the lookahead distance may also be reduced to the lower limit, for example. Here, the lookahead time may range from about 0.5 seconds to about 1.5 seconds. The lookahead time may be inversely proportional to a gain of one or more control loops, such as a heading error tracking control loop, etc., used in generating a navigation response in a vehicle 200. For example, the gain of the heading error tracking control loop may be determined in accordance with a bandwidth of each of a yaw rate loop, a steering actuator loop, and dynamics of a vehicle in a lateral direction thereof or the like. Hence, the higher the gain of the heading error tracking control loop, the shorter the lookahead time.

Subsequently, in step S576, the processing unit 110 may determine an amount of a heading error and a value of a yaw rate command based on the lookahead point determined in step S574. Here, the processing unit 110 may determine the presence of the heading error by calculating an arctangent of the lookahead point, such as arctan (X₁/Z₁), for example. Further, the processing unit 110 may determine the yaw rate command as a product of an azimuth error and a high-level control gain. The high-level control gain may be equal to a value calculated as 2/lookahead time, if the look ahead distance is not the lower limit. By contrast, if the look ahead distance is the lower limit, the high-level control gain can be a value calculated by the formula of 2×a speed of a vehicle 200/look ahead distance.

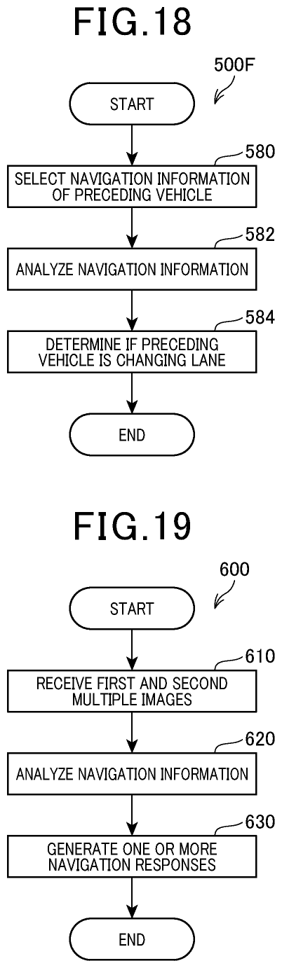

FIG. 18 is a flowchart illustrating an exemplary process 500F of determining whether a preceding vehicle is changing lane according to one embodiment of the present disclosure. Specifically, in step S580, the processing unit 110 may select navigation information of a preceding vehicle (e.g., another vehicle traveling ahead of an own vehicle 200). The processing unit 110 may then determine a position, a speed (i.e., a direction and a speed) and/or an acceleration of the preceding vehicle by using the technologies described earlier with reference to FIGS. 13 and 14. Further, the processing unit 110 may determine one or more road polynomials, a lookahead point of the vehicle 200 (i.e., preceding vehicle) and/or a snail trail (e.g., an assembly of points describing a course along which the preceding vehicle runs) by using the technologies described earlier with reference to FIG. 17.

Subsequently, in step S582, the processing unit 110 may analyze the navigation information selected in step S580. In one embodiment, the processing unit 110 may calculate a distance along a road between the snail trail and the road polynomial. If such a difference in distance along the snail trail exceeds a given threshold, the processing unit 110 may determine that the preceding vehicle is likely changing a lane. Here, the given threshold may be from about 0.1 meter to about 0.2 meters on a linear road, from about 0.3 meters to about 0.4 meters on a moderately curved road, and from about 0.5 meters to about 0.6 meters on a sharply curved road, for example. Otherwise, if multiple vehicles traveling ahead of the vehicle 200 are detected, the processing unit 110 may compare snail trails of these vehicles therebetween. Then, based on a result of the comparison, the processing unit 110 may determine that one of the vehicles with the snail trail not matching with the snail trail of the other vehicles is highly probably changing the lane. Further, the processing unit 110 may compare a curvature of a snail trail of a leading vehicle with an expected curvature of a road segment along which the leading vehicle is traveling. The expected curvature may be extracted from map data (e.g., data from a map database 160), polynomials of roads, and snail trails of other vehicles. The expected curvature may also be extracted from prior knowledge about roads and the like. Then, if a difference between the curvature of the snail trail and the expected curvature of the road segment exceeds a given threshold, the processing unit 110 may determine that the leading vehicle is likely to be changing the lane.

In yet another embodiment, the processing unit 110 may compare an instantaneous position of a preceding vehicle with a look ahead point of the vehicle 200 for a given period (e.g., about 0.5 seconds to about 1.5 seconds). Then, if a distance between the instantaneous position of the preceding vehicle and the look ahead point varies during the given period, and a cumulative sum of fluctuations of the distance exceeds a given threshold, the processing unit 110 may determine that the preceding vehicle is likely to be changing the lane. Here, the given threshold may be, for example, from about 0.3 meters to about 0.4 meters on a linear road, from about 0.7 meters to about 0.8 meters for a moderately curved road, and from about 1.3 meters to about 1.7 meters on a sharply curved road. In yet another embodiment, the processing unit 110 may analyze a geometry of the snail trail by comparing a lateral distance by which a preceding vehicle has traveled along the snail trail with an expected curvature of the snail trail. Here, a radius of the expected curvature may be calculated by the below listed calculation formula, wherein, & represents a horizontal traveling distance and δz represents a longitudinal traveling distance: (δ_{z}²+δₓ²)/2/(δₓ). Hence, when a difference between the lateral traveling distance and the expected radius of curvature exceeds a given threshold (e.g., from about 500 meters to about 700 meters), the processing unit 110 may determine that the preceding vehicle is likely to be changing the lane. In yet another embodiment, the processing unit 110 may analyze a position of a preceding vehicle. Specifically, when the position of the preceding vehicle obscures a road polynomial (e.g., the preceding vehicle is superimposed on the road polynomial as a result of calculation), the processing unit 110 may determine that the preceding vehicle is likely to be changing the lane. In yet another embodiment, when another vehicle is detected ahead of the preceding vehicle and snail trails of these two vehicles are not parallel with each other, the processing unit 110 may determine that the closer preceding vehicle to the own vehicle is likely to be changing lane.

Hence, in step S584, the processing unit 110 may determine whether the preceding vehicle 200 is changing the lane based on the analysis as performed in step S582. Here, the processing unit 110 may make determination by weighting and averaging individual analyses performed in step S582. For example, in such a method, a value 1 (one) may be assigned to a determination made by the processing unit 110 based on a given type of analysis that the preceding vehicle is likely to be changing a lane. By contrast, a value 0 (zero) is assigned to a determination made by the processing unit 110 that a preceding vehicle is unlikely to be changing the lane. Further, the different analyses performed in step S582 may be assigned with different weights. That is, each of the embodiments of the present disclosure is not limited to any specific combination of analyses and weights.

FIG. 19 is a flowchart illustrating an exemplary process 600 to cause generation of one or more navigation responses based on stereo image analysis according to one embodiment of the present disclosure. Specifically, in step S610, the processing unit 110 may receive first and second multiple images via the data interface 128. For example, a camera (e.g., the image acquirer 122 or 124 having the field of view 202 or 204) included in the image acquisition unit 120 may capture multiple images of a region in front of the vehicle 200 and transmit the images to the processing unit 110 via a digital connection system. Here, the digital connection system may be a wired connection system or a wireless connection system. In some embodiments, the processing unit 110 may receive the first and second multiple images via two or more data interfaces. However, the present disclosure is not limited to any particular data interface. Also, the present disclosure is not limited to any particular protocol.

Subsequently, in step S620, the processing unit 110 may execute instructions of the stereo image analysis module 404 and perform stereo image analysis of the first and second multiple images. The processing unit 110 may then create a 3D map of a region of a road in front of the vehicle and detect features, such as lane signs, vehicles, pedestrians, etc., included in the images. The processing unit 110 may also detect road signs, highway exit ramps, and traffic lights as the features in the images based on the 3D map. The processing unit 110 may further detect road hazards and the like as the features in the images based on the 3D map. The stereo image analysis may be similarly performed substantially as executed in applicable steps as described earlier with reference to FIGS. 13 to 16. For example, the processing unit 110 executes instructions of the stereo image analysis module 404 and detect candidate objects (e.g., vehicles, pedestrians, road markings, traffic lights, road hazards, etc.,) included in the first and second multiple images. The processing unit 110 then filters out a subset of candidate objects by using one of various criteria and performs multi-frame analysis of analyzing remaining candidate objects. The processing unit 110 then obtains measurements and determines a degree of confidence thereof. Here, in step S620 (i.e., analysis of navigation information), the processing unit 110 may utilize information from both of the first and the second multiple images rather than information from only one set of multiple images. For example, the processing unit 110 may analyze a difference in pixel data between candidate objects appearing in each of the first and the second multiple images. Alternatively, the processing unit 110 may analyze a difference in data subset between two streams of captured images of candidate objects appearing in each of the first and second multiple images. As yet another example, the processing unit 110 may estimate a position and/or a velocity of the candidate objects relative to the vehicle 200 by observing an event in which a candidate object appears in one of the multiple images but does not appear in the other multiple images. Yet alternatively, a position and/or a velocity of the candidate object relative to the vehicle 200 may be estimated based on other differences of an object appearing in two image streams. For example, the position, the velocity and/or an acceleration relative to the vehicle 200 may be determined based on a locus, a position, and movement characteristics of the object appearing as a feature in both of the image streams or the like.

Subsequently, in step 630, the processing unit 110 may execute instructions of the navigation response module 408 to cause the vehicle 200 to generate one or more navigation responses based on the analysis performed in step 620 and the technologies described earlier with reference to FIG. 4. Here, the navigation responses may include turns, lane shifting, and changes in acceleration, for example. The navigation responses may also include speed changes and braking or the like. In some embodiments, the processing unit 110 may use data obtained as a result of execution of instructions of the velocity-acceleration module 406. Hence, data obtained as a result of execution of the instruction of the velocity-acceleration module 406 can be used to cause the vehicle 200 to generate one or more navigation responses. Here, multiple navigation responses may be generated simultaneously, in order, or in a method of any combination thereof.

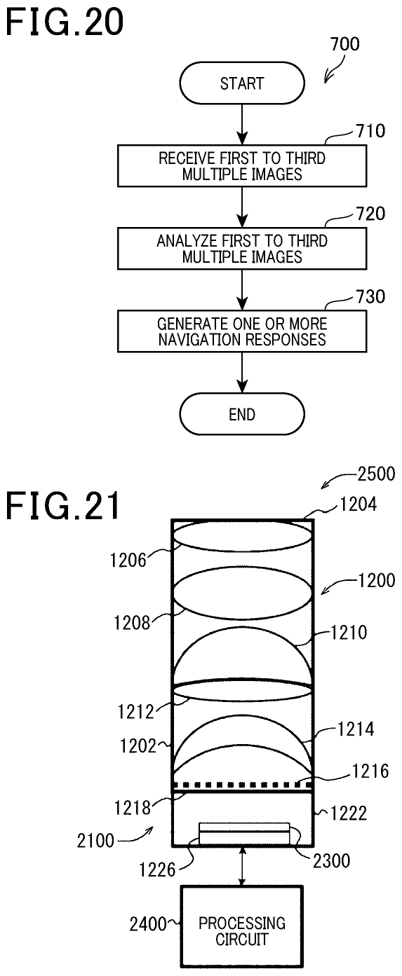

FIG. 20 is a flowchart illustrating an exemplary process 700 of causing a vehicle 200 to generate one or more navigation responses based on analysis of analyzing three sets of images according to one embodiment of the present disclosure. Specifically, in step 710, the processing unit 110 may receive first, second, and third multiple images via the data interface 128. For example, cameras included in the image acquisition unit 120, such as an image acquirer 122, 124, and 126 having fields of view 202, 204, and 206, etc., may capture multiple images of forward and/or sideward areas of the vehicle 200, and send the images to the processing unit 110 via a digital connection. In some embodiments, the processing unit 110 may receive multiple first, second, and third images via three or more data interfaces. For example, each of the image acquirers 122, 124 and 126 may have a data interface for communicating data to the processing unit 110. However, the present disclosure is not limited to any given data interface or even protocol.

Subsequently, in step 720, the processing unit 110 may analyze first, second and third multiple images and detects features, such as lane signs, vehicles, pedestrians, etc., included in the images. The processing unit 110 further detects features included in the images, such as road signs, highway exit ramps, traffic lights, etc. The processing unit 110 further detects features included in the images, such as road hazards, etc. Such analysis may be substantially similarly performed as performed in the steps described earlier with reference to FIGS. 13 to 16 and 19. That is, the processing unit 110 may perform monocular image analysis of analyzing each of the first, second, and third multiple images, for example. Here, the monocular image analysis can be performed by executing instructions of the monocular image analysis module 402 and performing the steps as described earlier with reference to FIGS. 13 to 16. Alternatively, the processing unit 110 may perform stereo image analysis of analyzing a first combination of the first and second multiple images, a second combination of the second and third multiple images, and/or a third combination of the first and third multiple images. Here, the stereo image analysis is performed by executing instructions of the stereo image analysis module 404 and performing the steps as described earlier with reference to FIG. 19. Information processed corresponding to the analysis of analyzing the first, second, and/or third multiple images may be combined. Further, in some embodiments, the processing unit 110 may perform a combination of the monocular and the stereo image analyses. For example, the processing unit 110 may perform monocular image analysis by analyzing the first multiple images and stereo image analysis by analyzing the second and third multiple images. Here, monocular image analysis is executed by executing instructions of the monocular image analysis module 402. Also, the stereo image analysis is executed by performing instructions of the stereo image analysis module 404. Here, positions of the image acquirers 122, 124 and 126 and the fields of view 202, 204 and 206 thereof may affect to selection of a type of analysis of analyzing the first, second, and third multiple images. However, the present disclosure disclosed heretofore is not limited to a specific image acquirer 122, 124, or 126, or a type of analysis performed for first, second, and third multiple images.

In some embodiments, the processing unit 110 may test the imaging system 100 based on images acquired and analyzed in steps S710 and S720. Such a test may provide an indicator indicating overall performance of the imaging system 100 in relation to the image acquirers 122, 124, and 126 having given configurations. For example, the processing unit 110 may determine a percentage of each of false hit and mistake. Here, the false hit represents a situation in which the imaging system 100 erroneously determines a presence of a vehicle or a pedestrian. The mistake represents overlooking such an object.

Subsequently, in step S730, the processing unit 110 may cause the vehicle 200 to generate one or more navigation responses based on information obtained from either all the first, second, and third multiple images or any two of the first, second, and third multiple images. Here, selection of such two groups of multiple images among the first, second and third multiple images may at least depend on one of factors related to the object. For example, the factor includes the number, a type, and a size of objects detected in each of the multiple images or the like. Also, the processing unit 110 can select two groups of such multiple images based on image quality, resolution, and an effective field of view reflected in an image. The processing unit 110 can also select such two groups based on the number of frames taken, and a degree of actual presence (i.e., appearance) of one or more objects of interest in a frame or the like. Here, the degree of actual presence in a frame means either a frequency of frames in which objects appear, or a proportion of a size of an object to an entire size of the frame in which the object appears and the like.

Further, in some embodiments, the processing unit 110 may select two groups of multiple images among the first, second, and third multiple images based on a degree by which information derived from one image source matches with information derived from another image source. For example, the processing unit 110 may process information derived from each of the image acquirers 122, 124, and 126, and identify a visual indicator consistently appearing in the groups of multiple images captured from the image acquirers 122, 124 and 126 based on a combination of these-information. Here, the visual indicator includes lane markings, a vehicle and its position and/or course as detected, and a traffic light as detected or the like.

For example, the processing unit 110 may combine information which is derived from each of the image acquirers 122, 124, and 126 and processed. The processing unit 110 may then determine presence of a visual indicator in the groups of multiple images captured from the image acquirers 122, 124 and 126 consistent with each other. Specifically, the processing unit 110 combines information (i.e., a group of multiple images) derived from each of the image acquirers 122, 124 and 126 and having been processed regardless that monocular analysis, stereo analysis, or any combination of the two analyses is performed. Here, the visual indicators included in the images captured from the image acquirers 122, 124 and 126 consistent with each other represent a lane marking, a vehicle as detected, a position of the vehicle, and/or a course of the vehicle. Such a visual indicator may also be a traffic light as detected or the like. Further, the processing unit 110 may exclude information (i.e., a group of multiple images) inconsistent with the other information. Here, the inconsistent information may be a vehicle changing a lane, a lane model indicating a vehicle running too close to the vehicle 200, etc. In this way, the processing unit 110 may select information (i.e., a group of multiple images) derived from two groups of the first, second, and third multiple images based on the determination of consistency and inconsistency.

Here, the navigation response may include turning, lane shifting, and a change in acceleration or the like. The processing unit 110 may cause the vehicle 200 to generate one or more navigation responses based on the analysis performed in step S720 and the technologies as described earlier with reference to FIG. 4. The processing unit 110 may also cause the vehicle 200 to generate one or more navigation responses by using data obtained by executing instructions of the velocity-acceleration module 406. In some embodiments, the processing unit 110 may cause the vehicle 200 to generate one or more navigation responses based on a relative position, a relative velocity, and/or a relative acceleration between the vehicle 200 and an object detected in any one of the first, second, and third multiple images. These multiple navigation responses may occur simultaneously, in a sequence, or in any combination of these orders.

FIG. 21 is a diagram schematically illustrating components of an exemplary imaging apparatus 2500 used as an image acquirer. The exemplary imaging apparatus 2500 includes a lens system 1200 coupled to an image sensor 2100 acting as an imager system. The lens system 1200 is housed in a lens barrel 1202 having a front cover glass 1204 and a rear cover glass 1218. The exemplary lens system 1200 includes a synthetic lens comprising a first biconvex lens 1206, a second biconvex lens 1208, a first positive meniscus lens 1210 and a biconvex lens 1212. The exemplary lens system 1200 also includes a second positive meniscus lens 1214. The lens system 1200 also includes a cut filter 1216 that attenuates light of IR (Infra-Red rays) and UV (Ultra-Violet rays) of a spectral range, projected from the lens system 1200 to the image sensor 2100. Since the lens system 1200 is configured to provide a relatively large MTF (Modulation Transfer Function) when receiving light in a spectral range from red to green, the cut filter 1216 may be configured to attenuate at least a portion of light in a spectral range of blue in addition to the light in the spectral ranges of IR and UV. Here, at least one of the biconvex lenses 1206, 1208 and 1212, the first positive meniscus lens 1210, and the second positive meniscus lens 1214 may be either spherical or aspherical as lens elements. The lens element that constitutes the lens, that is, the positive meniscus lens 1210 and the biconvex lens 1212 may be joined by using optical cement or are separated from each other by air. However, such a lens configuration is just one example and is optionally altered. That is, other configurations that meet design rules as described hereinbelow with reference to Tables 1, 2 and 3 may be used instead of the lens system 1200.

Further, the imaging apparatus 2500 may also include a housing 1222, a color filter array 2300, and an APS image sensor (hereinafter simply referred to as an image sensor) 1226. The image sensor may be a CMOS (Complementary Metal Oxide

Semiconductor) sensor. Here, a relative size of each of the color filter array 2300 and the image sensor 1226 is exaggerated for easy comprehension of the imaging apparatus 2500. The image sensor 1226 is positioned relative to the lens system 1200 in the housing 1222 so that an image from a scene is focused on an upper surface of the image sensor 1226 via the color filter array 2300. Pixel data captured by the image sensor 1226 is provided to a processing circuit 2400. The processing circuit 2400 is enabled to control operation of the image sensor 1226.

In an automotive usage, image data in a blue spectral range may be less important sometimes than image data in a red to green spectral range. In general, a way to improve a quantum efficiency of an imager without increasing the number of apertures of a lens is to design a lens to produce a clearer image in a red to green spectral range than in the blue spectral range while employing a color filter adaptive to the lens. However, it is not always necessary to adopt such a method of improving the quantum efficiency of the imager by designing the lens in this way. That is, when an importance of the image data in the blue spectral range is not less than an importance of the image data in the red to green spectral range, the cut filter 1216 need not be configured to attenuate light in the blue spectral range.

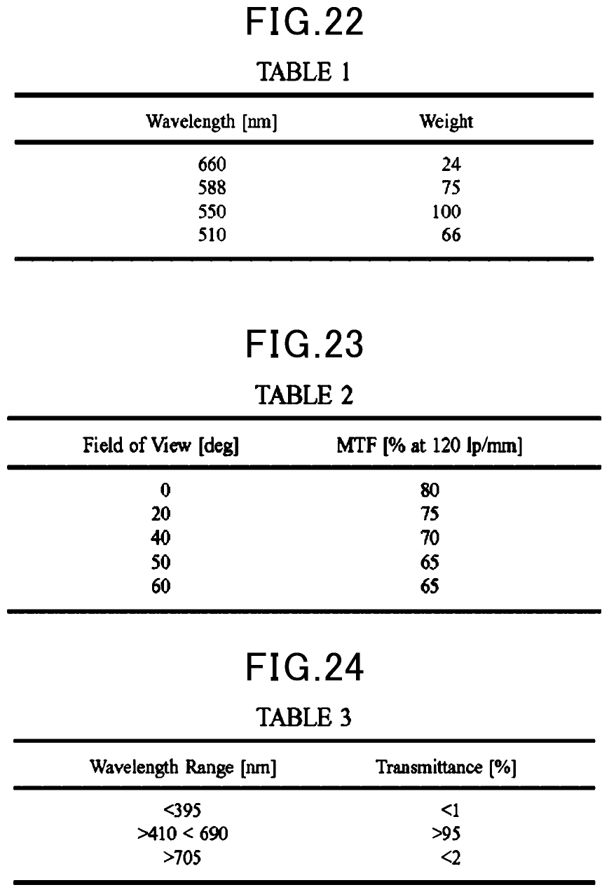

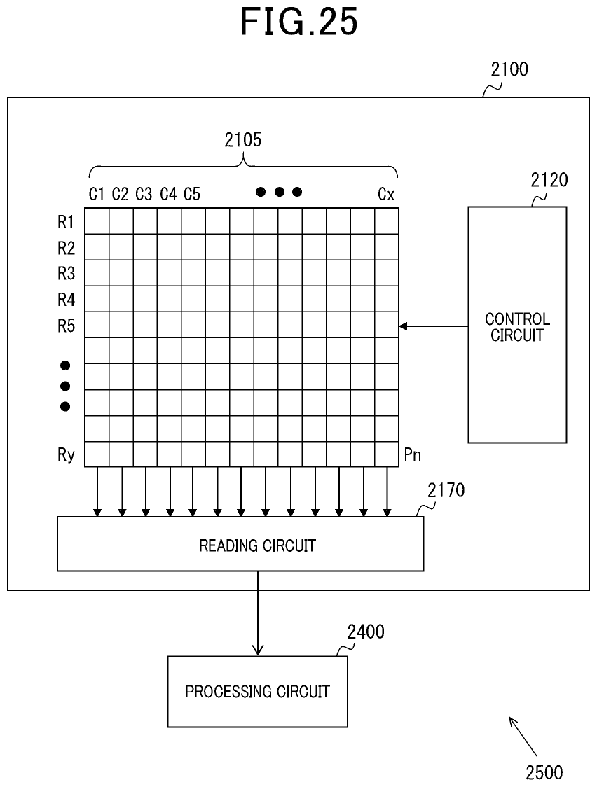

Here, the lens system 1200 illustrated in FIG. 21 as one example can be designed in accordance with design rules illustrated in Table 1 of FIG. 22, Table 2 of FIG. 23, and Table 3 of FIG. 4. Among these Tables, the Table 1 illustrates weighting on a wavelength used in lens design. The Table 2 illustrates a polychromatic MTF used in lens design in which a wavelength is weighted as illustrated in the Table 1. The Table 3 illustrates a parameter of the cut filter 1216 configured to attenuate both UV light having a wavelength less than a cutoff wavelength ranging from about 395 nm to about 410 nm and IR light having a wavelength greater than the cutoff wavelength ranging from about 690 nm to about 705 nm. As described above, in some embodiments, the cut filter 1216 may be configured to attenuate light having a wavelength of less than about 500 nm, thereby attenuating not only light in the spectral range from blue to purple, but also light in the UV spectral range.

Further, the above-described design rule specifies a lens system in which an optical focal point of light in the spectral range from red to green is emphasized more than others in a field of view of about 60 degrees. In addition, the weight design rules of Table 1 places a higher value on a wavelength of yellow than wavelengths of red and blue. In this way, a visual field design rule shown in Tables 1 to 3 specifies a relatively higher MTF for light in the spectral range at least from red to green in the entire field of view of the lens system. Such a lens system is used by the processing circuit 2400 included in the imaging apparatus 2500 and can identify items of interest included in the entire field of view of the imaging apparatus 2500.

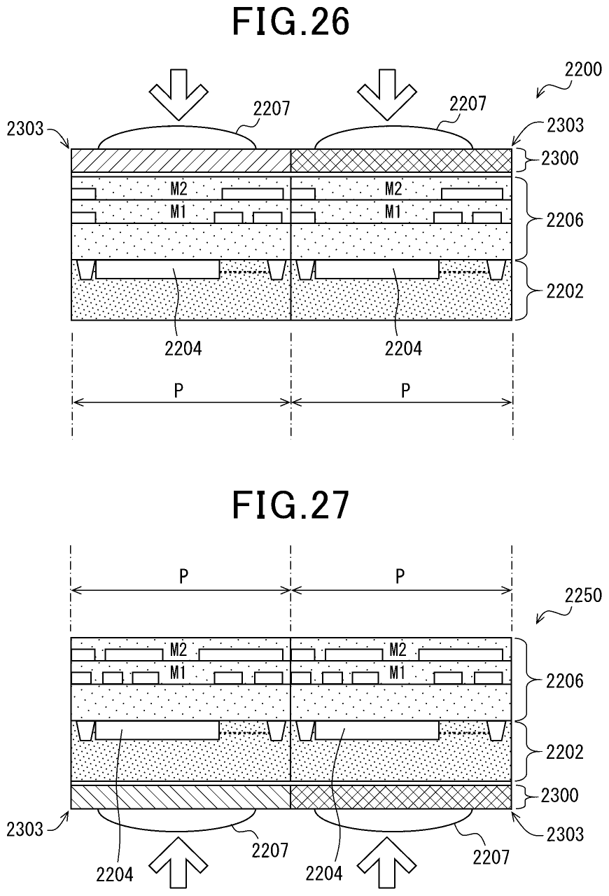

FIG. 25 illustrates one example of the image sensor 2100 comprising a pixel array 2105, a reading circuit 2170 coupled to the pixel array 2105, and a control circuit 2120 coupled to the pixel array 2105. Here, the pixel array 2105 includes either individual image sensors having X pixel columns and Y pixel rows, or a two-dimensional (2D) array composed of pixels (e.g., pixels P1, P2, Pn). The pixel array 2105 acts as either an image sensor with front illumination as illustrated in FIG. 26, or an image sensor with rear illumination as illustrated in FIG. 27. As illustrated, each pixel P of the array 2105 is arranged in rows (e.g., rows from R1 to Ry) and columns (e.g., columns from C1 to Cx) to obtain image data of an individual, a position and/or an object. Then, these pixels P render a 2D image of the person, the place and/or the object based on the image data. As further described later, the pixel array 2105 may assign a color to each pixel P by using a color filter array 2300 coupled to the pixel array 2105. Here, a single pixel serves as a single point in a color image composed of an assembly of points. A unit (single/one) color filter described later in detail corresponds to the single pixel.

Hence, when each pixel of the pixel array 2105 has acquired image data (i.e., an image electric charge), the image data is then read by the reading circuit 2170. The image data is then transferred to the processing circuit 2400 for the purpose of storage and additional processing or the like therein. The reading circuit 2170 includes an amplifier circuit and an analog/digital conversion circuit (ADC) or other circuits. The processing circuit 2400 is coupled to the reading circuit 2170. The processing circuit 2400 executes a functional logic. The processing circuit 2400 may process (or manipulate) the image data by applying thereto a cropping process, a rotating process, and a red-eye removal process as a post-image action while storing the image data. The processing circuit 2400 may also process or manipulate the image data by applying thereto a brightness adjustment process and a contrast adjustment process or the like as a post-image action while storing the image data. In one embodiment, the processing circuit 2400 is also used to process the image data to correct (i.e., reduce or remove) fixed pattern noise. Further, the control circuit 2120 coupled to the pixel array 2105 is used for the purpose of controlling operation characteristics of the pixel array 2105. For example, the control circuit 2120 generates a shutter signal for controlling image acquisition by the pixel array 2105.

FIG. 26 is a cross-sectional view illustrating a pair of exemplary front illumination pixels (hereinafter referred to as a FSI pixel) 2200 included in a CMOS image sensor. Here, a front side of the FSI pixel 2200 is a side of a substrate 2202, on which both of a photoelectric conversion element 2204 and a corresponding pixel circuit to collectively serve as an optical sensing region, and A metal stack 2206 to redistribute the signals are formed in this order. The metal stack 2206 includes metal layers M1 and M2 each forming a pattern to form an optical passage. Hence, through this passage, light incident on the FSI pixel 2200 reaches the photoelectric conversion element 2204. In order to act as a color image sensor, the front side of the FSI pixel 2200 includes a color filter array 2300. The color filter array 2300 includes primary color individual color filters 2303. The primary color individual color filter 2303 is disposed below a micro-lens 2207 that effectively converges incident light at the photoelectric conversion element 2204. Here, a cross-sectional view of FIG. 26 only illustrates two primary color individual color filters 2303 for simplicity. The color filter array 2300 includes a minimum repetition unit 2302 as described later more in detail.

FIG. 27 is a cross-sectional view illustrating a pair of exemplary rear illumination pixels (hereinafter simply referred to as a BSI pixel) 2250 included in a CMOS image sensor according to one embodiment of the present disclosure. By contrast to a situation illustrated in FIG. 26, a front side of the BSI pixel 2250 is a side of the color filter 2303, on which a substrate 2202, both of photoelectric conversion elements 2204 and a corresponding pixel circuit, and a metal stack 2206 to redistribute signals are formed in this order.

In order to constitute a color image sensor, the rear side of the BSI pixel 2250 includes a color filter array 2300. The color filter array 2300 includes primary color individual color filters 2303. The primary color individual color filter 2303 is disposed below the micro-lens 2207. However, a cross-sectional view of FIG. 27 only illustrates two primary color individual color filters 2303 for simplicity. Here, the color filter array 2300 is a color filter array formed from one of the minimum repetition units described later in more detail. The micro-lens 2207 effectively converges incident light at a photoelectric conversion element 2204. With such rear illumination by the BSI pixel 2250, a metal interconnection line of the metal stack 2206 does not interfere with a course formed between an object to be imaged and the photoelectric conversion element 2204, so that a larger signal can be generated by the photoelectric conversion element 2204.

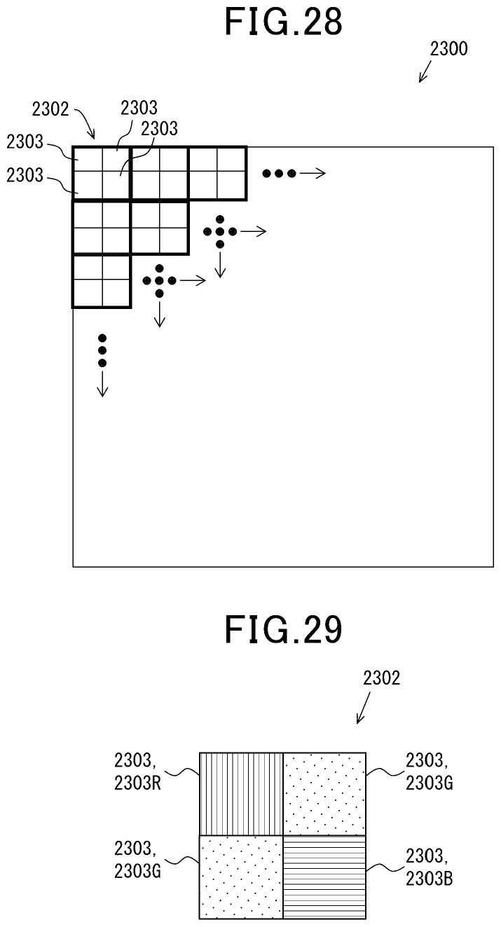

FIG. 28 illustrates the color filter array 2300 and a single set of minimum repetition unit 2302 in a tile state to form the color filter array 2300. The color filter array 2300 includes the number of individual primary color individual color filters 2303 substantially corresponding to the number of individual pixels P in the pixel array 2105 to which the color filter array 2300 is being coupled or will be coupled. The individual primary color individual color filter 2303 is optically coupled to the corresponding individual pixel P in the pixel array 2105, and has a given spectral photo-responsibility selected from a single set of spectral photo-responsibilities. The given spectral photo-responsibility has high sensitivity to a given portion of an electromagnetic spectrum and low sensitivity to other portions of the spectrum. Although a pixel P itself does not have a color, since the color filter array 2300 separately assigns a light response to each pixel P by placing the primary color individual color filter 2303 on the pixel P, the pixel P is commonly regarded as a pixel P having a given light response. Hence, a pixel P is referred to as a blue pixel when it is combined with a blue filter. Also, another pixel P is referred to as a green pixel when it is combined with a green filter. Further, yet another pixel P is referred to as a red pixel when it is combined with a red filter.

The individual primary color individual color filters 2303 of the color filter array 2300 are grouped into a minimum repetition unit 2302. The primary color individual color filter 2303 is a color filter disposed corresponding to a single photoelectric conversion element 2204. The minimum repetition unit 2302 is tiled vertically and horizontally as illustrated by arrows to form the color filter array 2300. Here, the minimum repetition unit 2302 is a repetition unit that does not have fewer individual filters. The color filter array 2300 can include many different repeating units. However, a repetition unit is not the minimum repetition unit if there is another repetition unit in the array with fewer individual filters. In other examples of the color filter array 2300, the minimum repetition unit may be greater or less than the minimum repetition unit 2302 of this example.

FIG. 29 illustrates a configuration of a color filter of the minimum repetition unit 2302. The minimum repetition unit 2302 illustrated in FIG. 29 includes four primary color individual color-filters 2303 independent from each other. Specifically, the minimum repetition unit 2302 includes a single red individual color filter 2303R, a single blue individual color filter 2303B, and two green individual color filters 2303G.

As shown, a shape of each primary color individual color filter 2303 is square, and four primary color individual color filters 2303 are arranged in two rows and columns. Hence, the minimum repetition unit 2302 also has a square shape. However, the present disclosure is not limited thereto, and a shape of the primary color individual color filter 2303 is not necessarily square.

Further, as shown in FIG. 29, in the minimum repetition unit 2302, a red individual color filter 2303R, a green individual color filter 2303G and a blue individual color filter 2303B are arranged by forming a Bayer array.

Hence, the red individual color filter 2303R transmits light of red serving as one of three primary colors. In addition, the red individual color filter 2303R also transmits light of a primary color different from the corresponding primary color (i.e., red) although transmittance thereof is not as much as red.

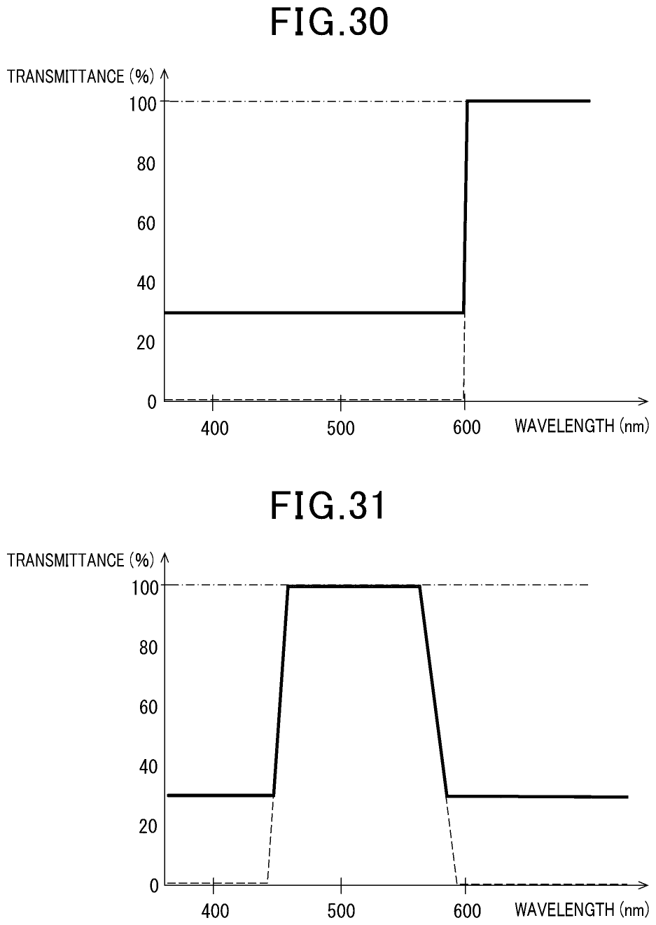

FIG. 30 is a graph illustrating a relation between a transmittance of the red individual color filter 2303R and a wavelength. In FIG. 30, a solid line illustrates the transmittance of the red individual color filter 2303R. A broken line represents transmittance of a general red filter to be compared. Although it depends on the definition, the transmittance of red is around 650 nm in the graph. The red individual color filter 2303R has a transmittance of about 100% for red and thus allows red light to permeate. However, since this is just an example, the present disclosure is not limited to a transmittance of about 100% for red light. That is, the red individual color filter 2303R may be enough only with a higher transmittance for red light than that for other light of primary colors.

Further, a wavelength of green light is around 540 nm. A wavelength of blue light is around 400 nm. The general red filter illustrated by the broken line in the graph for comparison almost never allows light of the other primary colors to permeate. By contrast, the red individual color filter 2303R transmits light of primary colors other than the red color even though a transmittance thereof is not as much as red. Specifically, as shown in FIG. 30 as an example, the red individual color filter 2303R has a transmittance of about 30% for other primary colors.

That is, since almost all objects of imaging targets have a spectrum with a wider base instead of a single wavelength (i.e., a mono-color), an amount of light from the object detected by a pixel of each of RGB colors can be increased and a sensitivity is accordingly improved if a wavelength range of the light detected by the pixel of each of RGB colors is expanded. Hence, one embodiment of the present disclosure expands a wavelength range of the light detected by the pixel of each of RGB colors to meet the following inequality.
Black and White>One Embodiment>Ordinary RGB

Here, sensitivities are calculated as described below. First, it is premised that an object is white, and an intensity of light (L) is even in a range of wavelengths from 380 nm to 680 nm. It is also premised that an image sensor with a filter has a transmittance of 0% in a range of wavelengths excluding from 380 nm to 680 nm, and 100% in a range of wavelengths from 380 nm to 680 nm. It is further premised that RBG color filters output wavelengths within a range of wavelengths from 380 nm to 680 nm. In particular, a color filter B has a transmittance of 100% in a range of wavelengths from 380 nm to 480 nm, a color filter G has a transmittance of 100% in a range of wavelengths from 480 nm to 580 nm, and a color filter G has a transmittance of 100% in a range of wavelengths from 580 nm to 680 nm. It is also premised that RGB type filters of this embodiment transmit 30% of other wavelengths, respectively. Hence, sensitivities of the ordinary RGB pixels are calculated as follows:

R=100 nm×L×1.0,

G=100 nm×L×1.0,

B=100 nm×L×1.0.

By contrast, each of sensitivities of RGB type filters in this embodiment is calculated by the following equalities and is 1.9 times as much as each of the ordinary RGB pixels.

R=100 nm×L×1.0+300 nm×L×0.3=100 nm×L×1.9,

G=100 nm×L×1.0+300 nm×L×0.3=100 nm×L×1.9,

B=100 nm×L×1.0+300 nm×L×0.3=100 nm×L×1.9.

However, the rate of 30% is just an example of a transmittance which is higher than a lower effective transmittance.

Further, the lower effective transmittance is a lower limit of the transmittance effective for improving sensitivity of the image sensor 2100. The lower effective transmittance may be appropriately determined in accordance with a specification or the like as required for an image sensor 2100. Further, the lower effective transmittance is at least a level capable of distinguishing the transmittance from a noise level. Hence, for example, the lower effective transmittance may be one of 10%, 15%, and 20%. Also, the lower effective transmittance may be 25%, for example.

Further, as shown by the graph of FIG. 30, according to the red individual color filter 2303R, a transmittance is substantially the same not only near wavelengths of respective blue and green light, but also around a wavelength of colors other than red. Similarly, a transmittance is substantially the same (i.e., uniform) in a range of a wavelength, in which the general red filter does not allow light to permeate.

FIG. 31 is a graph schematically illustrating a relation between a transmittance of the green individual color filter 2303G and a wavelength. In FIG. 31, a solid line illustrates a transmittance of the green individual color filter 2303G. A broken line indicates a transmittance of a general green filter for comparison. The green individual color filter 2303G has a transmittance of about 100% for green light and thus allows green light to permeate. However, since the rate of 100% is just an example, the green individual color filter 2303G may be suitable only with a higher transmittance for green than that for other primary colors.

In view of this, according to the green individual color filter 2303G illustrated in FIG. 31 as one example, a transmittance of each of colors other than green including the other primary colors is about 30%. Hence, the green individual color filter 2303G also has a higher transmittance for the other primary colors than the above-described lower effective transmittance.

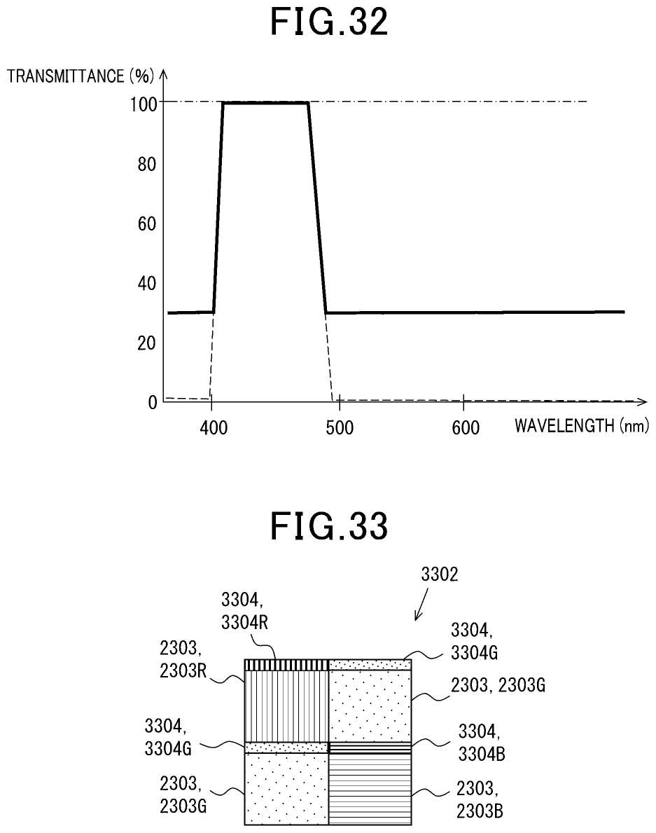

FIG. 32 schematically illustrates a relation between a transmittance of a blue type individual color filter 2303B and a wavelength. In FIG. 32, a solid line illustrates a transmittance of the blue individual color filter 2303B. A broken line represents a transmittance of a general blue filter to be compared. The blue type individual color filter 2303B has a transmittance of about 100% for blue and thus allows blue light to permeate. However, since the rate of 100% is just one example, the blue individual color filter 2303B may be suitable only with a higher transmittance for blue than that for the other primary colors.

Further, as shown in FIG. 32 as one example, the blue individual color filter 2303B has a transmittance of about 30% for colors other than blue including the other primary colors. Hence, the blue individual color filter 2303B also has a higher transmittance for the other primary colors than the lower effective transmittance.

Further, as shown, each of the red individual color filter 2303R, the green individual color filter 2303G, and the blue individual color filter 2303B has substantially the same transmittance for colors other than a corresponding primary color.

Accordingly, in each of filters of the red individual color filter 2303R, the blue individual color filter 2303B and the green individual color filter 2303G, a transmittance is higher over the entire visible region than the lower effective transmittance, while particularly increasing a transmittance of a corresponding primary color. Since the image senser 2100 includes the red individual color filter 2303R, the blue individual color filter 2303B, and the green individual color filter 2303G, the image sensor 2100 can effectively improve an own sensitivity when compared with a system with a color filter not transmitting colors other than the corresponding primary color.

In addition, a sensitivity can be improved by using a filter having a higher transmittance for a primary color other than a corresponding primary color than the effective transmittance. Hence, as an individual color filter, a difference in signal level can be more effectively reduced when compared with a primary color filter that does not allow primary colors other than a corresponding primary color to permeate, or a system separately equipped with the clear filter.

Next, a second embodiment of the present disclosure will be hereinbelow described with reference to FIG. 33. In the second and subsequent embodiments, devices or members having the same reference number are identical to the devices or the members already described except as otherwise specifically mentioned. Further, in case the early described configuration is partially modified and described, remaining parts of the configuration can adopt that of the already described embodiments.

As illustrated in FIG. 33, a minimum repetition unit 3302 may be adopted in this embodiment instead of the minimum repetition unit 2302 described in the first embodiment. That is, the minimum repetition unit 3302 includes a red type individual color filter 2303R, green type individual color filters 2303G, and a blue type individual color filter 2303B each having the same characteristics as the individual color filters described in the first embodiment. However, different from the first embodiment, these filters of the second embodiment have rectangular shapes. This is because, the minimum repetition unit 3302 can additionally accommodate a rectangular red sub-primary color filter section 3304R, green sub-primary color filter sections 3304G and a blue sub-primary color filter section 3304B while maintaining a square. That is, by forming the primary color type individual color filter 2303 and the sub-primary color filter section 3304 in the above-described shape, the minimum repetition unit 3302 becomes square. However, the present disclosure is not limited to a square, and the shape of the minimum repetition unit 3302 can be altered. That is, the shape of each of the primary color type individual color filter 2303 and the sub-primary color filter section 3304 is just one example, and can be changed to the other various shapes.

Here, the sub-primary color filter section 3304 constitutes a set with the primary color type individual color filter 2303 of the same color type. However, the sub-primary color filter section 3304 is smaller than the primary color filter section 2303. For example, the sub-primary color filter section 3304 has an area less than a half of a combination area obtained by combining the sub-primary color filter section 3304 and the primary color filter section 2303. More specifically, the area of the sub-primary color filter section 3304 is less than a half of the primary color filter section 2303.

The red sub-primary color filter section 3304R constitutes a set with the red type individual color filter 2303R. The green sub-primary color filter section 3304G also constitutes a set together with the green type individual color filter 2303G. The blue sub-primary color filter section 3304B similarly constitutes a set together with the blue type individual color filter 2303B. Thus, a single individual color filter includes the set of the primary color type individual color filter 2303 and the sub-primary color filter section 3304.

The sub-primary color filter section 3304 has a lower transmittance of a primary color other than a corresponding primary color than the primary color type individual color filter 2303. An example of a relation between a wavelength and a transmittance of the sub-primary color filter section 3304 can be the same as the general primary color filter illustrated by broken lines in any one of FIGS. 30, 31 and 32.

As shown, each sub-primary color filter section 3304 is disposed adjacent to the primary color type individual color filter 2303 to collectively constitute the set of filters. That is, collectively constituting the set means that colors of these filters are the same. However, the sub-primary color filter section 3304 does not need to be disposed adjacent to the primary color type individual color filer 2303 to collectively constitute the set of filters.

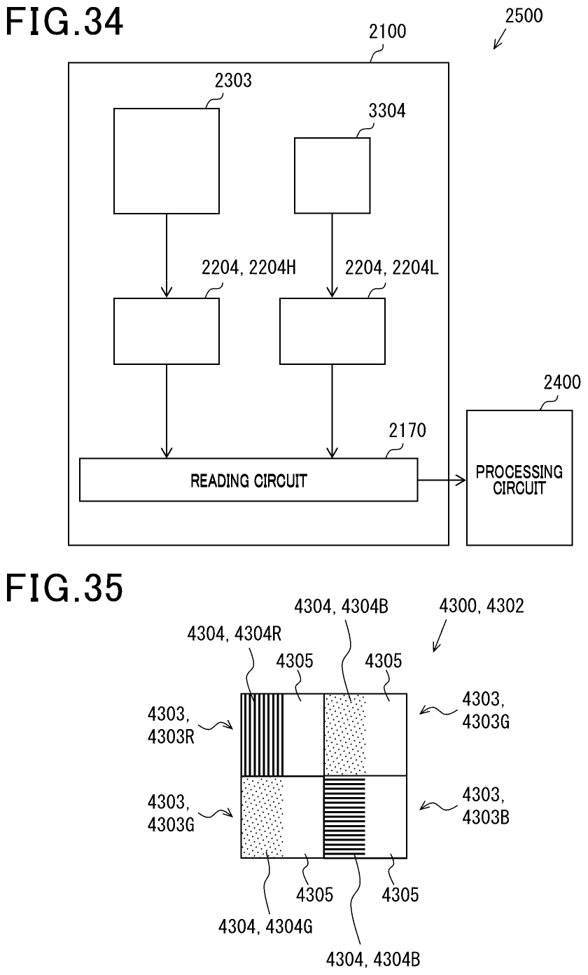

An exemplary structure of an imaging apparatus 2500 according to the second embodiment of the present disclosure is described with reference to FIG. 34. As illustrated there, the imaging apparatus 2500 separately includes a photoelectric conversion element 2204 (i.e., left side) provided corresponding to the primary color type individual color filter 2303 and another photoelectric conversion element 2204 (i.e., right side) provided corresponding to the sub-primary color filter section 3304.

A reading circuit 2170 may separate signals into a signal output from the photoelectric conversion element 2204 corresponding to the primary color individual color filter 2303 and a signal output from the photoelectric conversion element 2204 corresponding to the sub-primary color filter section 3304. The reading circuit 2170 may then output these signals to the processing circuit 2400.

The primary color type individual color filter 2303 has a higher light transmittance than the sub-primary color filter section 3304. Hence, the photoelectric conversion element 2204 provided corresponding to the primary color type individual color filter 2303 is more sensitive than the photoelectric conversion element 2204 provided corresponding to the sub-primary color filter section 3304. Hereinbelow, the photoelectric conversion element 2204 provided corresponding to the primary color type individual color filter 2303 is referred to as a high-sensitivity pixel 2204H. The photoelectric conversion element 2204 provided corresponding to the sub-primary color filter section 3304 may be referred to as a low-sensitivity pixel 2204L. Further, the processing circuit 2400 may be enabled to generate a color per pixel of a color image by using only one of the signals outputs from the high-sensitivity pixel 2204H and the low-sensitivity pixel 2204L. Also, the processing circuit 2400 may generate a color per pixel of a color image by using both of these two types of signals.

Here, the low sensitivity pixel 2204L is regarded to be a pixel that more hardly saturates than the high-sensitivity pixel 2204H. Since the image sensor 2100 includes both the high-sensitivity pixel 2204H and the low-sensitivity pixel 2204L, the image sensor 2100 can more effectively widen a dynamic range than a system where only the high-sensitivity pixels 2204H are provided.

Further, the processing circuit 2400 uses a different correction coefficient in a situation where a color image is generated by using a signal output from the high-sensitivity pixel 2204H from another situation where a color image is generated by using a signal output from the low-sensitivity pixel 2204L. One example of the correction coefficient may be a white balance setting value (i.e., a preset white balance) or a color matrix setting value and the like. Another example of the correction coefficient may be a correction coefficient used in calculating a luminance value. The white balance setting value is a value that greatly corrects a signal output from the low sensitivity pixel 2204L more than a signal output from the high-sensitivity pixel 2204H. By contrast, the setting value of the color matrix is a coefficient that greatly corrects a signal output from the high sensitivity pixel 2204H to be greater more than a signal output from the low sensitivity pixel 2204L. Further, the correction coefficient used in calculating a luminance value is a coefficient that greatly corrects a signal output from the low-sensitivity pixel 2204L more than a signal output from the high-sensitivity pixel 2204H. Further, the correction coefficients used in correcting outputs from the low sensitivity pixel 2204L and the high-sensitivity pixel 2204H may be adjusted by a user separately.

Next, a third embodiment of the present disclosure will be hereinbelow described with reference to FIG. 35. FIG. 35 illustrates a minimum repetition unit 4302 of a color filter array 4300 according to the third embodiment of the present disclosure. Specifically, a size of the minimum repetition unit 4302 may be the same as the minimum repetition unit 2302 of the first embodiment. As shown, the minimum repetition unit 4302 has a shape formed by arranging four primary color type individual color filters 4303 in two rows and two columns. Configurations other than the color filter array 4300 are substantially the same as that in the first embodiment. Hence, a single photoelectric conversion element 2204 is disposed corresponding to each primary color type individual color filter 4303.

Further, the primary color type individual color filter 4303 includes a red type individual color filter 4303R, green type individual color filters 4303G, and a blue type individual color filter 4303B. Specifically, the minimum repetition unit 4302 has a Bayer array in which a single red type individual color filter 4303R, two green type individual color filters 4303G, and a single blue type individual color filter 4303B are arranged.

Further, each primary color type individual color filter 4303 includes a primary color filter section 4304 and a clear filter section 4305. Specifically, in this embodiment, the primary color type individual color filter 4303 is formed in a square shape and is divided into two quarters in a rectangular shape such that one quarter is a primary color filter section 4304 and the other quarter is a clear filter section 4305.

Further, the red type individual color filter 4303R includes a red filter section 4304R as a primary color filter section 4304. Also, the green type individual color filter 4303G includes a green filter section 4304G as a primary color filter section 4304. The blue type individual color filter 4303B also includes a blue filter section 4304B as a primary color filter section 4304. Here, characteristics of the red filter section 4304R are substantially the same as that of the red sub-primary color filter section 3304R. Similarly, characteristics of the green filter section 4304G are substantially the same as that of the green sub-primary color filter section 3304G. Also, characteristics of the blue filter section 4304B are substantially the same as that of the blue sub-primary color filter section 3304B.

Here, each of the clear filter sections 4305 includes a colorless transparent filter. Hence, since it is colorless and transparent, the clear filter section 4305 is more sensitive than the primary color filter section 4304. Here, the filter having higher sensitivity than the primary color filter section 4304 is either a filter capable of increasing sensitivity even when substantially the same photoelectric conversion element 2204 is used, or a filter having a higher light transmittance than the primary color filter section 4304.

Further, as shown, according to the third embodiment, the minimum repetition unit 4302 includes four primary color type individual color filters 4303. The primary color type individual color filter 4303 includes the primary color filter section 4304 and the clear filter section 4305. Hence, sensitivity is more effectively improved by the third embodiment than a situation where a primary color type individual color filter 4303 is entirely composed of the primary color filter sections 4304. As a result, since sensitivity is improved by provision of the clear filter section 4305, a difference in signal level between pixels P can be reduced when compared with a system in which the clear filter is provided separately from the primary color filter as an individual color filter.

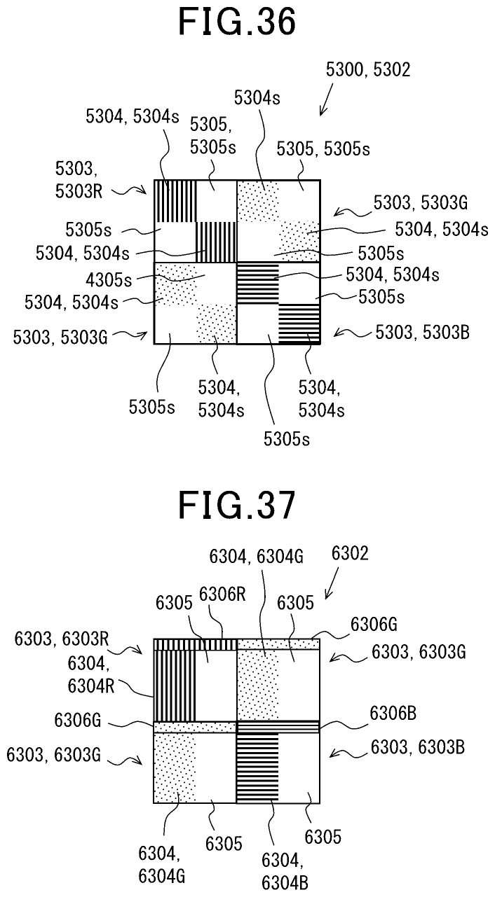

Next, a fourth embodiment will be hereinbelow described with reference to FIG. 36. As shown in FIG. 36, each primary color type individual color filter 5303 constituting a minimum repetition unit 5302 is divided into four small squares. Then, of the four small squares, a pair of squares shifted vertically and horizontally from each other (i.e., arranged downward to the right) serve as sub-primary color filter sections 5304s. Of the four small squares, remaining two squares serve as sub-clear filter sections 5305s. Specifically, a clear filter section 5305 is divided into two (i.e., multiple) sub-clear filter sections 5305s in one primary color type individual color filter 5303. The sub-clear filter section 5305s has high sensitivity to serve as a sub-high sensitivity filter section.

Further, the primary color filter section 5304 is also divided into multiple sub-primary color filter sections 5304s. However, although each primary color type individual color filter 5303 is configured by each of the sections as illustrated in FIG. 36, a ratio of an area between the primary color filter section 5304 and the clear filter section 5305 in each primary color type individual color filter 5303 is the same as that illustrated in FIG. 35. Hence, as similar to a system illustrated in FIG. 35, according to this embodiment, sensitivity is more effectively improved than a system in that the primary color type individual color filter 5303 is entirely composed of the primary color filter sections 5304. At the same time, a difference in signal level between pixels P can be more effectively reduced when compared with a system in which a clear filter is separately provided as an individual color filter from the primary color filter.

Next, a fifth embodiment is hereinbelow described with reference to FIG. 37. As illustrated in FIG. 37, a minimum repetition unit 6302 of this embodiment includes multiple primary color type individual color filters 6303 each having substantially the same characteristics as the filters employed in the third embodiment. That is, the minimum repetition unit 6302 includes a red type individual color filter 6303R, green type individual color filters 6303G, and a blue type individual color filter 6303B each having substantially the same characteristics as the filters described in the third embodiment. However, in the fifth embodiment, a shape of each of the section and filters is rectangular. This is because, the minimum repetition unit 6302 can accommodate a red sub-primary color filter section 6306R, green sub-primary color filter sections 6306G, and a blue sub-primary color filter section 6306B while maintaining a square shape as a whole. Each of the red sub-primary color filter section 6306R, the green sub-primary color filter sections 6306G, and the blue sub-primary color filter section 6306B has substantially the same shape as the sub-primary color filter section 3304. Here, the shape of the primary color type individual color filter 6303 and the sub-primary color filter section 6306 is just an example and can be changed to other various shapes.

Each primary color type individual color filter 6303 includes a primary color filter section 6304 and a clear filter section 6305. Hence, the red type individual color filter 6303R includes a red filter section 6304R and a red sub-primary color filter section 6306R collectively serving as the primary color filter section 6304. Similarly, the green type individual color filter 6303G includes a green filter section 6304G and a green sub-primary color filter section 6306G collectively serving as the primary color filter section 6304. Also, the blue type individual color filter 6303B includes a blue filter section 6304B and a blue sub-primary color filter section 6306B collectively serving as the primary color filter section 6304.

Here, characteristics of the red filter section 6304R and the red sub-primary color filter section 6306R are substantially the same as that of the red sub-primary color filter section 3304R. Also, characteristics of the green filter section 6304G and the green sub-primary color filter section 6306G are substantially the same as that of the green sub-primary color filter section 3304G. Similarly, characteristics of the blue filter section 6304B and the blue sub-primary color filter section 6306B are the same as that of the blue sub-primary color filter section 3304B.

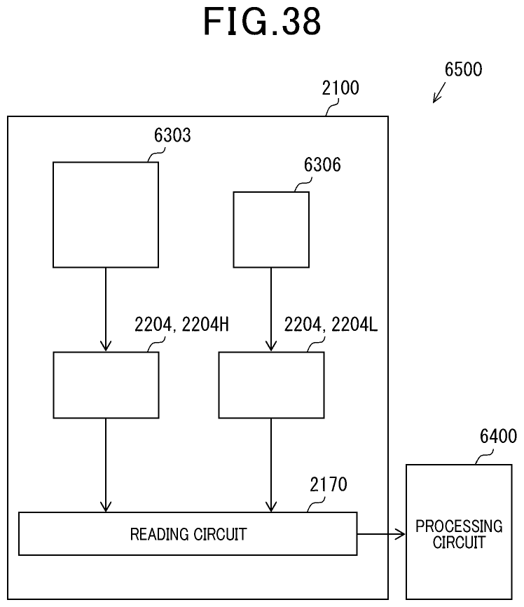

FIG. 38 partially illustrates a configuration of an imaging apparatus 6500 according to the fifth embodiment. As illustrated in FIG. 38, the imaging apparatus 6500 separately includes a photoelectric conversion element 2204 corresponding to the primary color type individual color filter 6303 and a photoelectric conversion element 2204 corresponding to the sub-primary color filter section 6306.

A reading circuit 2170 separates signals into a signal output from the photoelectric conversion element 2204 provided corresponding to the primary color type individual color filter 6303 and a signal output from the photoelectric conversion element 2204 provided corresponding to the sub-primary color filter section 6306. The reading circuit 2170 then outputs these signals to a processing circuit 6400.

The primary color type individual color filter 6303 has a higher light transmittance than the sub-primary color filter section 6306. Hence, the photoelectric conversion element 2204 provided corresponding to the primary color type individual color filter 6303 has a high-sensitivity pixel 2204H. By contrast, the photoelectric conversion element 2204 provided corresponding to the sub-primary color filter section 3304 has a low-sensitivity pixel 2204L.

Further, similar to the processing circuit 2400, a processing circuit 6400 also can generate a color image by using either or both of the high-sensitivity pixel 2204H and the low-sensitivity pixel 2204L. Hence, the processing circuit 6400 may use a different correction coefficient in correcting a signal output from the high-sensitivity pixel 2204H from a correction coefficient used in correcting a signal output from the low sensitivity pixel 2204L.

Here, as the correction coefficient, one or more correction coefficients used in calculating a white balance setting value, a color matrix setting value, and a luminance value are used. A relation of magnitude of the correction coefficient between the high-sensitivity pixel 2204H and the low-sensitivity pixel 2204L is the same as that between the high-sensitivity pixel 2204H and the low-sensitivity pixel 2204L of the second embodiment.

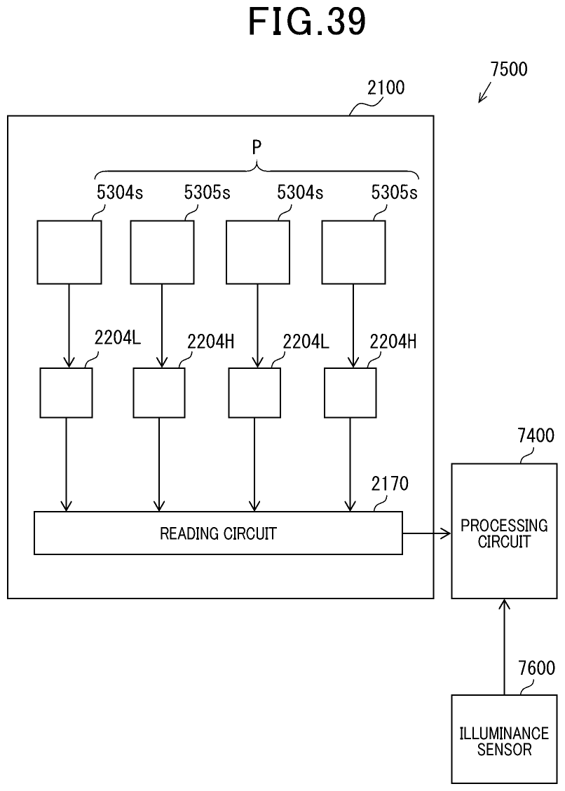

Next, a sixth embodiment of the present disclosure is hereinbelow described with reference to FIG. 39. FIG. 39 partially illustrates a configuration of an imaging apparatus 6500 according to the sixth embodiment. As illustrated there, an image sensor 2100 of the sixth embodiment includes the color filter array 5300 illustrated in FIG. 36. Hence, a single pixel P includes two sub-primary color filter sections 5304s and two sub-clear filter sections 5305s.

Hence, the image sensor 2100 of the sixth embodiment includes two photoelectric conversion elements 2204 corresponding to the two sub-clear filter sections 5305s, respectively. Also, two photoelectric conversion elements 2204 are provided corresponding to the two sub-primary color filter sections 5304s, respectively.

A processing circuit 7400 is employed and enabled to separately acquire signals output from the photoelectric conversion elements 2204 respectively by controlling the reading circuit 2170. The processing circuit 7400 executes an image processing method of generating color images. As a step of performing the image processing method, the processing circuit 7400 adjusts the number of photoelectric conversion elements 2204 used in generating a color of a single pixel P, out of (i.e., by selectively using) two photoelectric conversion elements 2204 provided corresponding to the two sub-clear filter sections 5305s, in accordance with ambient brightness of the imaging apparatus 7500.

Since two sub-clear filter sections 5305s are employed, the number of effective photoelectric conversion elements 2204 corresponding to the sub-clear filter sections 5305s may be 0, 1, and 2 (i.e., three ways are present) for a single pixel P. Similarly, when one or two thresholds dividing degrees of brightness is prepared, brightness of ambient of the imaging apparatus 7500 can be divided into two or three.

Further, the number of photoelectric conversion elements 2204 provided in the processing circuit 7400 corresponding to the sub-clearer filter sections 5305s used in generating a color of a single pixel P is increased as the brightness of ambient of the imaging apparatus 7500 decreases (i.e., as ambient becomes darker). Hence, an illuminance sensor 7600 is installed around the imaging apparatus 7500, and the processing circuit 7400 detects ambient brightness of the imaging apparatus 7500 based on a detection signal of illuminance generated by the illuminance sensor 7600. Otherwise, the processing circuit 7400 may acquire a detection signal of brightness from the illuminance sensor 7600. Otherwise, the processing circuit 7400 may acquire a value indicating a degree of brightness determined by other processors based on a detection signal of illuminance generated by the illuminance sensor 7600.

Further, the processing circuit 7400 changes a correction coefficient used in correcting a signal output from the photoelectric conversion element 2204 in accordance with the number of photoelectric conversion elements 2204 used in generating a color of a single pixel P. The correction coefficient can correct one or more values of a white balance setting value, a color matrix setting value, and a luminance value, for example.

Here, the more photoelectric conversion elements 2204 provided corresponding to the sub-clear filter sections 5305s, the thinner the color before correction. Then, the processing circuit 7400 increasingly adjusts a correction coefficient to be a level capable of solving a problem of thinning of color as the number of photoelectric conversion elements 2204 provided corresponding to the sub-clear filter sections 5305s increases. An exemplary adjustment is hereinbelow described more in detail.

Specifically, an amount of correction coefficient used in correcting a white balance setting value is decreased as the number of photoelectric conversion elements 2204 provided corresponding to the sub-clear filter sections 5305s increases. Further, an amount of correction coefficient used in correcting a color matrix setting value is increased as the number of photoelectric conversion elements 2204 provided corresponding to the sub-clear filter sections 5305s increases. That is because the more the number of photoelectric conversion elements 2204 provided corresponding to the sub-clearer filter sections 5305s, the lighter the color before correction. Further, the correction coefficient for correcting the luminance value is designated as a value that decreases as the number of photoelectric conversion elements 2204 provided corresponding to the sub clear filter sections 5305s increases. This is because the more the number of photoelectric conversion elements 2204 provided corresponding to the sub clear filter sections 5305s, the higher the brightness of the signal before correction. A correction coefficient that varies in accordance with a degree of brightness of ambient of the imaging apparatus 7500 is predetermined as an initial setting based on actual measurement. Further, a correction coefficient used in correcting a white balance setting value is adjusted to cause a whitish subject to be white in a sufficiently bright area in order to prevent overcorrection. For example, such an adjustment is performed in a place illuminated by headlights of a vehicle 200 and is bright enough.

Further, the imaging apparatus 7500 of the sixth embodiment adjusts the number of low-sensitivity pixels 2204L used in generating a color of a single pixel P, out of (i.e., by selectively using) multiple low-sensitivity pixels 2204L provided corresponding to the multiple sub-clear filter sections 5305s, in accordance with a degree of brightness of ambient of the imaging apparatus 7500. With this, even if the brightness of ambient of the imaging apparatus 7500 changes, a difference in signal level among signals output from the photoelectric conversion elements 2204 provided corresponding to pixels P can be reduced.

Heretofore, although various embodiments of the present disclosure are described, the present disclosure is not limited thereto and at least the following modifications may be included therein. Hence, other various changes and modifications that do not deviate from the gist of the present disclosure can be included within a range of the present disclosure.

Hereinbelow various modifications of the above-described embodiment are briefly described. Initially, a first modification is hereinbelow briefly described. In the above-described embodiments, all of the primary color individual color filters 2303, 4303, 5303 and 6303 employed in the respective minimum repetition units 2302, 3302, 4302 and 6302 are arranged by forming the Bayer arrays. However, the present disclosure is not limited thereto, and various arrangements can be employed. That is, for example, the primary color type individual color filters 2303, 4303, 5303 and 6303 included in the minimum repetition unit can employ various arrays, such as an oblique Bayer array, a quad Bayer array, etc.

Next, a second modification is hereinbelow briefly described. The minimum repetition unit is effective (i.e., suitable) if it includes at least one primary color type individual color filter 2303, 4303, 5303 or 6303. Further, the minimum repetition unit may include an individual color filter other than the primary color type individual color filters 2303, 4303, 5303 and 6303. For example, as such an individual color filter other than the primary color type individual color filter, a clear individual filter that is a colorless transparent individual color filter is exemplified. Also, a yellow individual color filter that is an individual color filter causing yellow to permeate can be exemplified. Further, as the individual color filter, a complementary color type individual color filter may be used. Here, cyan and magenta can be exemplified as examples of the complementary color.

Further, the minimum repetition unit can be the following combinations of individual color filters, wherein R represents a red type individual color filter, G represents a green type individual color filter, B represents a blue type individual color filter. Further, C represents a clear individual color filter, Ye represents a yellow individual color filter, and Cy represents a cyan individual color filter. That is, the minimum repetition unit can be RGCB, RYeYeB, and RYeYeCy. Also, the minimum repetition unit can be RYeYeG, RYeYeC, and RYeYeYe. Further, the minimum repetition unit can be RCCB, RCCCy and RCCG. Further, the minimum repetition unit can be RCCC and RCCYe or the like.

Next, a third modification is hereinbelow briefly described. In the above-described embodiments, the clear filter sections 4305, 5305 and 6305 acting as high sensitivity filter sections are colorless and transparent. However, the filter used in the high-sensitivity filter section is not necessarily colorless and transparent. That is, if sensitivity of the filter used in the high-sensitivity filter section is higher than that of each of the primary color filter sections 4304, 5304 and 6304, the filter used in the high-sensitivity filter section is not needed to be colorless and transparent. For example, a yellow filter can be used in the high-sensitivity filter section.

Next, a fourth modification is hereinbelow briefly described. In the fifth embodiment, the minimum repetition unit 5302 can be used instead of the minimum repetition unit 6302. In such a situation, the low-sensitivity pixel 2204L is disposed at a given position allowing the low-sensitivity pixel 2204L to receive light transmitting one of the two sub-primary color filter sections 5304s. Similarly, the high-sensitivity pixels 2204H are disposed at given positions allowing the high-sensitivity pixels 2204H to receive light transmitting the rest of the primary color type individual color filters 5303. Here, multiple high-sensitivity pixels 2204H can be provided in accordance with a shape of the remaining section of the primary color type individual color filters 5303.

Next, a fifth modification is hereinbelow briefly described. The imaging apparatus 2500, 6500 or 7500 of the above-described embodiments are used to cause the vehicle 200 to generate the navigation response. However, the imaging apparatus 2500, 6500 or 7500 can be used for other applications, such as a drive recorder application, etc. Further, the imaging apparatus 2500, 6500 or 7500 can be used for multiple applications. For example, the imaging apparatus 2500, 6500 or 7500 can be used to cause a vehicle 200 to generate navigation responses and to operate drive recorders at the same time.

Next, a sixth modification is hereinbelow briefly described. The processing unit 110, the control circuit 2120, and the processing circuit 2400, 6400 or 7400 as described in the present disclosure may be realized by a dedicated computer constituting a processor programmed to perform multiple functions. Also, methods of operating the processing unit 110, the control circuit 2120, and the processing circuit 2400, 6400 or 7400 may be realized by a dedicated computer constituting a processor programmed to perform multiple functions. Alternatively, the processing unit 110, the processing circuit 2400, 6400 or 7400 and methods of operating these circuits as described in the present disclosure may be realized by a dedicated hardware logic circuit. Otherwise, the processing unit 110, the processing circuit 2400, 6400 or 7400 and methods of operating these circuits as described in the present disclosure may be realized by one or more dedicated computers composed of a combination of a processor executing a computer program and one or more hardware logic circuits. The hardware logic circuits can be, for example, ASICs (Application Specific Integration Circuits) and FPGAs (Field Programmable Gate Arrays).

Further, the storage medium for storing computer program is not limited to the ROM. That is, the storage medium may be a computer readable non-transition tangible recording medium capable of causing a computer to read and execute the program stored therein as instructions. For example, a flash memory can store the above-described program as the storage.

Numerous additional modifications and variations of the present disclosure are possible in light of the above teachings. It is hence to be understood that within the scope of the appended claims, the present disclosure may be performed otherwise than as specifically described herein. For example, the present disclosure is not limited to the above-described image sensor and may be altered as appropriate. Further, the present disclosure is not limited to the above-described imaging apparatus and may be altered as appropriate. Further, the present disclosure is not limited to the above-described image processing method and may be altered as appropriate.

What is claimed is:

1. An image sensor comprising:
multiple photoelectric conversion elements; and
multiple individual color filters to generate multiple colors, the multiple individual color filters being arranged corresponding to the multiple photoelectric conversion elements, respectively,
wherein at least one of the multiple individual color filters includes a primary color type individual color filter,
the primary color type individual color filter transmitting light of a corresponding primary color and light of at least one of other primary colors than the corresponding primary color,
the primary color type individual color filter having a first given transmittance for light of the one of other primary colors than the corresponding primary color, at which the light of one of the other primary colors permeates the primary color type individual color filter,
the first given transmittance being higher than a lower limit of a transmittance improving a sensitivity of the image sensor.

2. The image sensor as claimed in claim 1, wherein the at least one of the multiple individual color filters includes:
a sub-primary color filter section constituting a set with the primary color type individual filter,
the sub-primary color filter having a second given transmittance for light of a primary color other than a corresponding primary color,
the second given transmittance being lower than the first given transmittance of the primary color type individual color filter for light of a primary color other than a corresponding primary color,
wherein the multiple photoelectric conversion elements are separately arranged corresponding to the multiple primary color type individual color filter and the sub primary color filter, respectively.

3. An imaging apparatus comprising:
the image sensor as claimed in claim 2; and
a processing circuit to generate a color image by correcting and processing signals output from the image sensor,
wherein the processing circuit generates the color image based on;
a first signal output from the photoelectric conversion elements correspondingly arranged to the primary color type individual filters and
a second signal output from the photoelectric conversion element correspondingly arranged to the sub-primary color filters,
wherein a correction coefficient used in correcting the signals-output from the photoelectric conversion elements correspondingly arranged to the primary color type individual filters and a correction coefficient used in correcting signals output from the photoelectric conversion element correspondingly arranged to the sub-primary color filter are different from each other.

4. An image sensor comprising:
multiple photoelectric conversion elements; and
multiple color individual color filters correspondingly arranged to the multiple photoelectric conversion elements, respectively,
wherein at least one of the multiple color individual color filters includes:
a primary color filter generating a corresponding primary color; and
a high sensitivity filter more sensitive than the primary color filter.

5. The image sensor according to claim 4, wherein the primary color filter section is divided into multiple pieces.

6. The image sensor as claimed in claim 5, wherein one of the multiple pieces of the primary color filter section constitutes a sub-primary color filter section having a smaller area than a half of the primary color filter, further comprising:
a low sensitivity pixel acting as a photoelectric conversion element correspondingly arranged to the sub-primary color filter section; and
a high-sensitivity pixel acting as a photoelectric conversion element correspondingly arranged to one or more remaining pieces of the primary color filter section.

7. An imaging apparatus comprising:
the image sensor as claimed in claim 6; and
a processing circuit to generate a color image by processing signals output from the image sensor;
wherein the processing circuit generates the color image by correcting signals output from both the low-sensitivity pixel and the high-sensitivity pixel,
wherein a correction coefficient used in correcting the signal output from the low sensitivity pixel and a correction coefficient used in correcting the signal output from the high sensitivity pixel are different from each other.

8. An imaging apparatus comprising:
the image sensor as claimed in claim 4; and
a processing circuit to generate a color image by processing signals output from the image sensor,
wherein the high sensitivity filter section is divided into multiple sub-high sensitivity filter sections,
wherein the multiple sub-high sensitivity filter sections are correspondingly arranged to the multiple photoelectric conversion elements, respectively,
wherein the processing circuit adjusts the number of photoelectric conversion elements used in generating a color of one pixel in accordance with an ambient luminance.

9. The imaging apparatus as claimed in claim 8,
wherein the processing circuit generates the color image by correcting the signals output from the photoelectric conversion elements,
wherein the processing circuit changes a correction coefficient used in correcting one or more signals output from the photoelectric conversion elements in accordance with the number of photoelectric conversion elements used in generating a color of a single pixel.

10. An image processing method comprising the steps of:
receiving incident light with multiple color individual color filters;
generating primary colors with a primary color filter section causing a part of the incident light to transmit a high sensitivity filter section having a higher sensitivity than the primary color filter section, the high sensitivity filter section being divided into multiple sub-high sensitivity filter sections, the multiple sub-high sensitivity filter sections being correspondingly arranged to the multiple photoelectric conversion elements, respectively, and
adjusting the number of photoelectric conversion elements used in generating a color of a single pixel in accordance with an ambient luminance;
performing multiple photoelectric conversion with multiple photoelectric conversion elements correspondingly arranged to the multiple color individual color filters, respectively, to obtain electric signals;
correcting the electric signals; and
generating a color image based on the electric signals as corrected.
